(19) United States
(12) Patent Application Publication
(10) Pub. No.: US 2025/0318398 A1
(43) Pub. Date: Oct. 9, 2025

(54) DISPLAY PANEL AND METHOD FOR MANUFACTURING THE SAME

(71) Applicant: Samsung Display Co., Ltd., Yongin-si (KR)

(72) Inventors: JEONGKI KIM, Yongin-si (KR); JANG-IL KIM, Yongin-si (KR); KYOUNGHAE MIN, Yongin-si (KR); SEONGYEON LEE, Yongin-si (KR); SUN-KYU JOO, Yongin-si (KR); SEOK-JOON HONG, Yongin-si (KR)

(73) Assignee: Samsung Display Co., Ltd., Yongin-si (KR)

(21) Appl. No.: 19/034,924

(22) Filed: Jan. 23, 2025

(30) Foreign Application Priority Data
Apr. 8, 2024 (KR) 10-2024-0047185

(51) Int. Cl. H10K 59/38; H10K 59/12; H10K 59/122

(52) U.S. Cl. CPC H10K 59/38; H10K 59/1201; H10K 59/122

(57) ABSTRACT

A display panel includes a display element layer including a light emitting element outputting source light, and an optical structure layer on the light emitting element and transmitting or converting the source light into light having a different wavelength. The optical structure layer includes a light control layer on the light emitting element. The light control layer includes a bank including a first and a second bank opening adjacent to each other, a first light control pattern inside the first bank opening, a second light control pattern inside the second bank opening, and a metal pattern disposed between the first and the second light control patterns. The bank is optically transparent, and a portion of the bank overlaps the first light control pattern. A portion of the metal pattern overlaps at least a portion of the first light control pattern and the second light control pattern.

### CROSS-REFERENCE TO RELATED APPLICATION(S)

This application claims priority to and benefits of Korean Patent Application No. 10-2024-0047185 under 35 U.S.C. § 119, filed on Apr. 8, 2024, in the Korean Intellectual Property Office (KIPO), the entire contents of which are incorporated herein by reference.

### BACKGROUND

### 1. Technical Field

The disclosure herein relates to a display panel having improved display efficiency while increasing in resolution and a method for manufacturing the same.

### 2. Description of the Related Art

A display panel includes a transmissive display panel selectively transmitting source light generated from a light source and an emission type display panel generating source light in the display panel itself. The display panel may include different kinds of light control patterns according to pixels for generating a color image. The light control patterns may transmit only a portion of a wavelength range of source light or convert a color of the source light. A portion of the light control patterns may not convert the color of the source light but convert characteristics the light.

### SUMMARY

The disclosure provides a display panel that is capable of implementing high resolution and has improved display efficiency.

The disclosure also provides a method for manufacturing a display panel having improved display efficiency.

According to an embodiment of the disclosure, a display panel may include a display element layer including a light emitting element that outputs a source light; and an optical structure layer disposed on the light emitting element and transmitting the source light or converting the source light into light having a different wavelength. In an embodiment, the optical structure layer may include a light control layer disposed on the light emitting element. In an embodiment, the light control layer may include a bank including a first bank opening and a second bank opening, which are adjacent to each other in a first direction, a first light control pattern disposed inside the first bank opening, a second light control pattern disposed inside the second bank opening, and a metal pattern disposed between the first light control pattern and the second light control pattern, In an embodiment, the bank may be optically transparent, and a portion of the bank may overlap the first light control pattern in a plan view. In an embodiment, a portion of the metal pattern may overlap at least a portion of the first light control pattern and the second light control pattern in a plan view.

In an embodiment, the bank may include a material having transmittance greater than or equal to about 85% in a visible light range.

In an embodiment, the metal pattern may be disposed between the first light control pattern and the bank and be in contact with at least a portion of a side surface of the first light control pattern.

In an embodiment, the metal pattern may be disposed between the second light control pattern and the bank and be in contact with at least a portion of a side surface of the second light control pattern.

In an embodiment, the metal pattern may have a ring shape along an edge of at least one of the first light control pattern and the second light control pattern in a plan view.

In an embodiment, the bank may further include a third bank opening adjacent to the second bank opening in the first direction. In an embodiment, the light control layer may further include a third light control pattern disposed inside the third bank opening.

In an embodiment, the metal pattern may include a first metal pattern disposed between the first light control pattern and the second light control pattern in the first direction, and a second metal pattern disposed between the second light control pattern and the third light control pattern in the first direction.

In an embodiment, each of the first light control pattern and the third light control pattern may include a photosensitive resin.

In an embodiment, each of the first light control pattern and the third light control pattern may include a scatterer and may not comprise an emitter.

In an embodiment, the second light control pattern may include a base resin and a quantum dot that is dispersed in the base resin.

In an embodiment, a thickness of the second light control pattern may be greater than a thickness of the first light control pattern.

In an embodiment, the bank may further include a first portion disposed on a surface of the first light control pattern, and a second portion that does not overlap the first light control pattern in a plan view. In an embodiment, the first portion and the second portion may have an integrated shape.

In an embodiment, a width of the first portion in the first direction may be greater than a width of the second portion in the first direction.

In an embodiment, the first portion may not overlap the first light control pattern and may overlap the second light control pattern in the first direction.

In an embodiment, a first bank area defined by the first bank opening may emit light having a first wavelength, and a second bank area defined by the second bank opening may emit light having a second wavelength. In an embodiment, the first wavelength may be less than the second wavelength.

In an embodiment, the display element layer may further include an encapsulation layer that covers the light emitting element. In an embodiment, the light control layer may be disposed directly on the encapsulation layer.

In an embodiment, the optical structure layer may further include a color filter layer including a first color filter and a second color filter. In an embodiment, the first color filter may overlap at least the first light control pattern in a plan view, and the second color filter may overlap at least the second light control pattern in a plan view.

In an embodiment, the light control layer may further include a barrier layer that covers a surface of each of the first light control pattern and the second light control pattern.

According to an embodiment of the disclosure, a display panel may include a display element layer including a light emitting element that outputs a source light, and an optical structure layer disposed on the light emitting element and transmitting the source light or converting the source light into light having a different wavelength. In an embodiment, the optical structure layer may include a light control layer disposed on the light emitting element. In an embodiment, the light control layer may include a bank including a first bank opening, a second bank opening, and a third bank opening, which are arranged in a first direction, a first light control pattern disposed inside the first bank opening, a second light control pattern disposed inside the second bank opening, a third light control pattern disposed inside the third bank opening, and a metal pattern disposed at least between the first light control pattern and the second light control pattern. In an embodiment, the bank may be optically transparent, each of the first light control pattern and the third light control pattern may include a photosensitive resin, and the second light control pattern may include a base resin and a quantum dot.

According to an embodiment of the disclosure, an electronic device may include a display panel, a window disposed on the display panel, and a housing disposed under the display panel. The display panel may include a display element layer comprising a light emitting element that outputs a source light, and an optical structure layer disposed on the light emitting element and transmitting the source light or converting the source light into light having a different wavelength. The optical structure layer may include a light control layer disposed on the light emitting element. The light control layer may include a bank comprising a first bank opening and a second bank opening, which are adjacent to each other in a first direction, a first light control pattern disposed inside the first bank opening, a second light control pattern disposed inside the second bank opening, and a metal pattern disposed between the first light control pattern and the second light control pattern. The bank may be optically transparent, a portion of the bank may overlap the first light control pattern in a plan view, and a portion of the metal pattern may overlap at least a portion of the first light control pattern and the second light control pattern in a plan view.

In an embodiment of the disclosure, a method for manufacturing a display panel may include preparing a display element layer including a light emitting element that outputs source light, and forming an optical structure layer on the light emitting element. In an embodiment, the forming of the optical structure layer may include patterning a first preliminary layer comprising a photosensitive material to form a first light control pattern, depositing and patterning a reflective metal layer to form a metal pattern, forming and patterning a preliminary bank layer that is optically transparent to form a bank including a first bank opening, through which a portion of the first light control pattern is exposed, and a second bank opening adjacent to the first bank opening in a first direction, and forming a second light control pattern in the second bank opening through an inkjet process. In an embodiment, a portion of the bank may overlap the first light control pattern in a plan view, and a portion of the metal pattern may overlap at least a portion of the first light control pattern and the second light control pattern in a plan view.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of a display panel according to an embodiment of the disclosure;

FIG. 1B is a schematic cross-sectional view of the display panel according to an embodiment of the disclosure;

FIG. 1C is a plan view of the display panel according to an embodiment of the disclosure;

FIG. 2 is an enlarged plan view illustrating a portion of the display panel according to an embodiment of the disclosure;

FIG. 3 is a schematic cross-sectional view illustrating a portion of the display panel according to an embodiment of the disclosure;

FIGS. 4A to 4D are schematic cross-sectional views illustrating a portion of the display panel according to an embodiment of the disclosure;

FIG. 5 is a schematic cross-sectional view of a light emitting element according to an embodiment of the disclosure;

FIGS. 6A to 6C are enlarged schematic cross-sectional views illustrating a portion of partial components of the display panel according to an embodiment of the disclosure;

FIGS. 7A and 7B are enlarged plan views illustrating a portion of partial components of the display panel according to an embodiment of the disclosure;

FIG. 8A is a flowchart illustrating a method for manufacturing a display panel according to an embodiment of the disclosure;

FIG. 8B is a flowchart illustrating a partial process in the method for manufacturing the display panel according to an embodiment of the disclosure; and

FIGS. 9A to 9E are schematic cross-sectional views illustrating a partial process in the method for manufacturing the display panel according to an embodiment of the disclosure.

FIG. 10A is a perspective view of an electronic device according to an embodiment of the disclosure.

FIG. 10B is an exploded perspective view of the electronic device according to an embodiment of the disclosure.

### DETAILED DESCRIPTION OF THE EMBODIMENTS

Hereinafter, embodiments of the disclosure will be described with reference to the accompanying drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals refer to like elements throughout. Also, in the figures, the thickness, ratio, and dimensions of components are exaggerated for clarity of illustration. In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In this specification, “directly disposed” may mean that there is no layer, film, region, plate, or the like between a portion of the layer, the layer, the region, the plate, or the like and the other portion. For example, “directly disposed” may mean being disposed without using an additional member such and an adhesion member between two layers or two members.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display panel and a method for manufacturing the display panel according to an embodiment of the disclosure will be described with reference to the accompanying drawings.

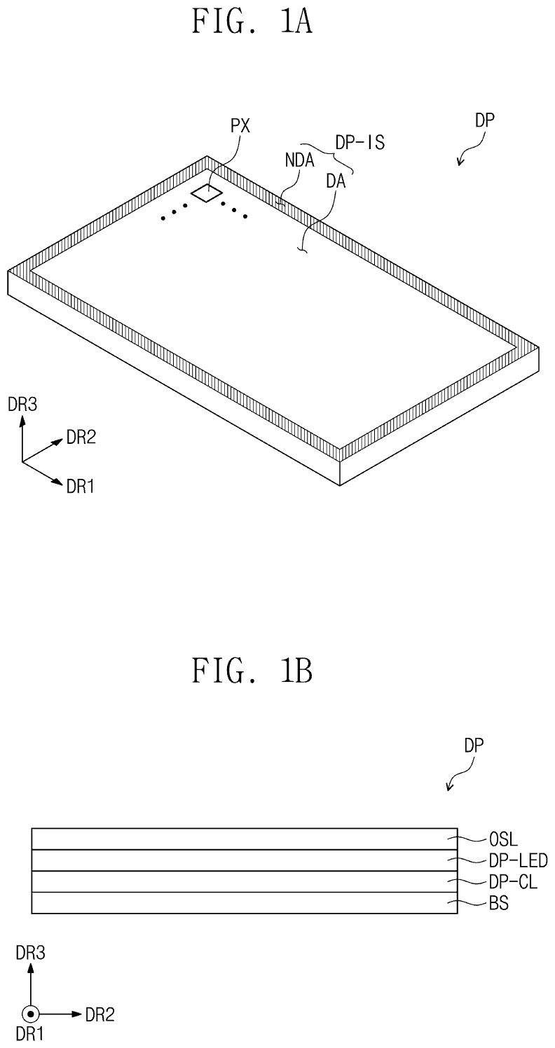

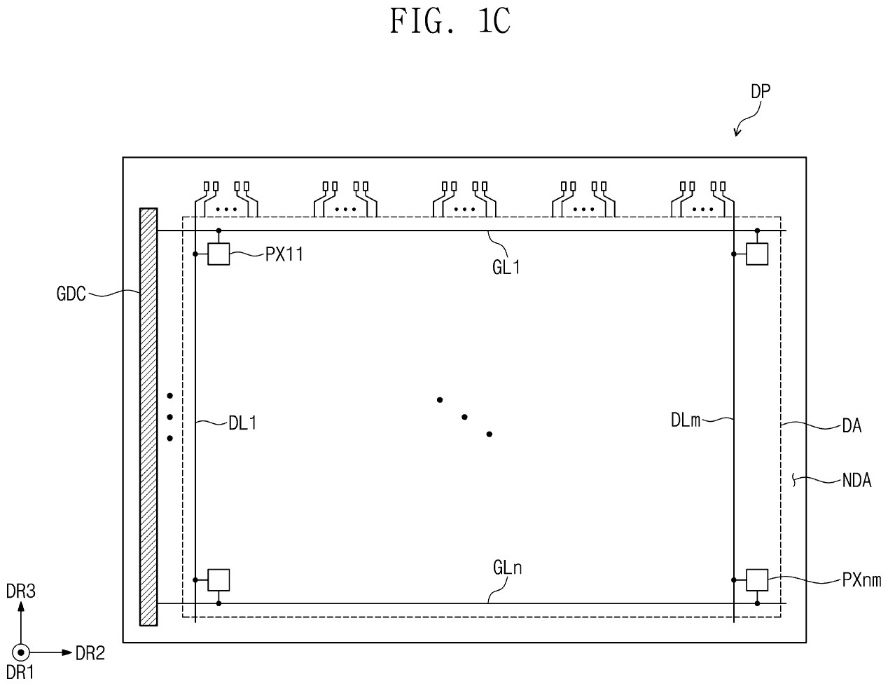

FIG. 1A is a perspective view of a display panel according to an embodiment of the disclosure. FIG. 1B is a schematic cross-sectional view of the display panel according to an embodiment of the disclosure. FIG. 1C is a plan view of the display panel according to an embodiment of the disclosure.

As illustrated in FIG. 1A, the display panel DP may display an image through a display surface DP-IS. The display surface DP-IS may be parallel to a surface defined by a first direction DR1 and a second direction DR2. The display surface DP-IS may include a display area DA and a non-display area NDA. A pixel PX may be disposed in the display area DA and may be not disposed in the non-display area NDA. The non-display area NDA may be formed along an edge of the display surface DP-IS. The non-display area NDA may surround the display area DA. However, the disclosure is not limited thereto, and in another embodiment of the disclosure, the non-display area NDA may be omitted or may be placed only at one side of the display area DA.

A normal direction of the display surface DP-IS, i.e., a thickness direction of the display panel DP may be indicated as a third direction DR3. A front surface (or a top surface) and a rear surface (or a bottom surface) of each of layers or units, which will be described below, may be distinguished by the third direction DR3. However, the first to third directions DR1, DR2, and DR3 described in the disclosure are not limited to the embodiment illustrated in the drawings.

Although the display panel DP having a planar display surface DP-IS is illustrated in FIG. 1A, the disclosure is not limited thereto. The display panel DP may include a curved display surface or a solid display surface. The solid display surface may include multiple display areas that face different directions.

As illustrated in FIG. 1B, the display panel DP may include a base substrate BS, a circuit element layer DP-CL, a display element layer DP-LED, and an optical structure layer OSL. The base substrate BS may include a synthetic resin substrate or a glass substrate. The circuit element layer DP-CL may include at least one insulating layer and a circuit element. The circuit element may include the signal line and the driving circuit of the pixel. The circuit element layer DP-CL may be formed through a process of forming an insulating layer, a semiconductor layer, and a conductive layer by coating or deposition and a process of patterning the insulating layer, the semiconductor layer, and the conductive layer by a photolithography process. The display element layer DP-LED may include at least a display element. The optical structure layer OSL may convert a color of light emitted from the display element. The optical structure layer OSL may include a structure for improving conversion efficiency of the light control pattern and light.

FIG. 1C schematically illustrates an arrangement relationship between signal lines GL1 to GLn and DL1 to DLm and pixels PX11 to PXnm in a plan view. The signal lines GL1 to GLn and DL1 to DLm may include multiple gate lines GL1 to GLn, and multiple data lines DL1 to DLm.

Each of the pixels PX11 to PXnm may be connected to a corresponding gate line of the gate lines GL1 to GLn and a corresponding data line of the data lines DL1 to DLm. Each of the pixels PX11 to PXnm may include a pixel driving circuit and a display element. Another type of signal lines may be provided on the display panel DP according to a configuration of the pixel driving circuit of the pixels PX11 to PXnm.

The gate driving circuit GDC may be integrated with the display panel DP through an oxide silicon gate driving circuit (OSG) process or an amorphous silicon gate driving circuit (ASG) process.

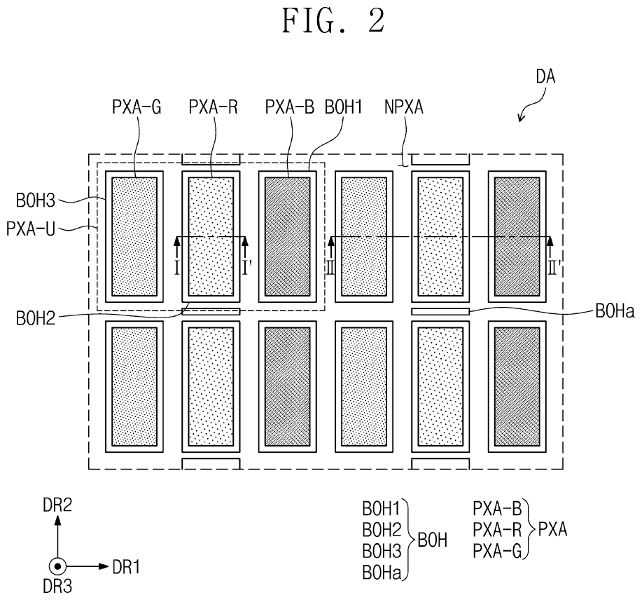

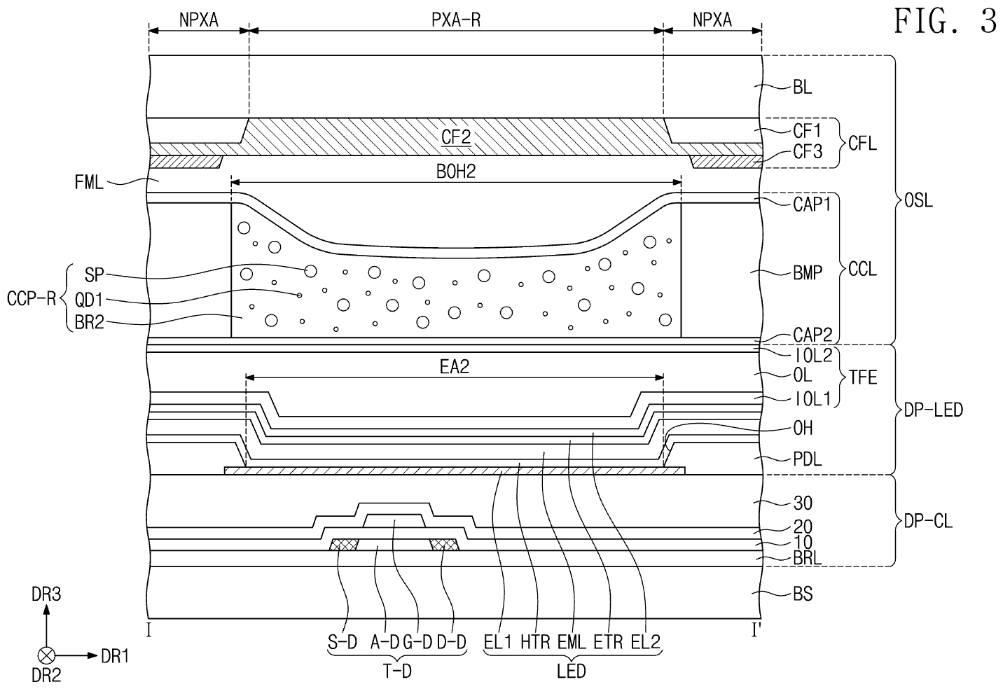

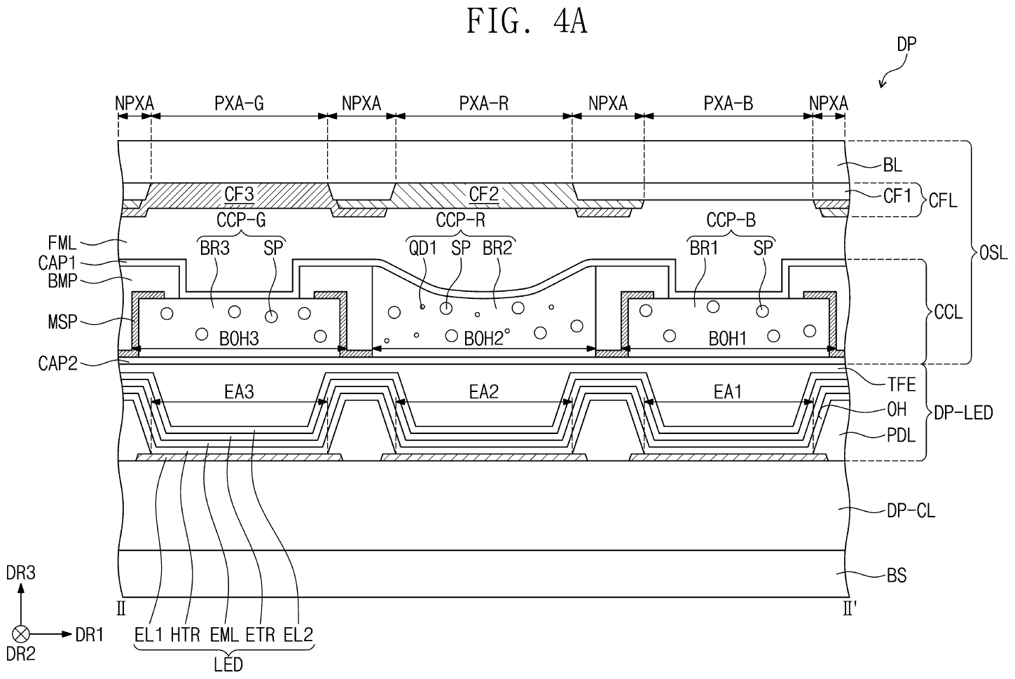

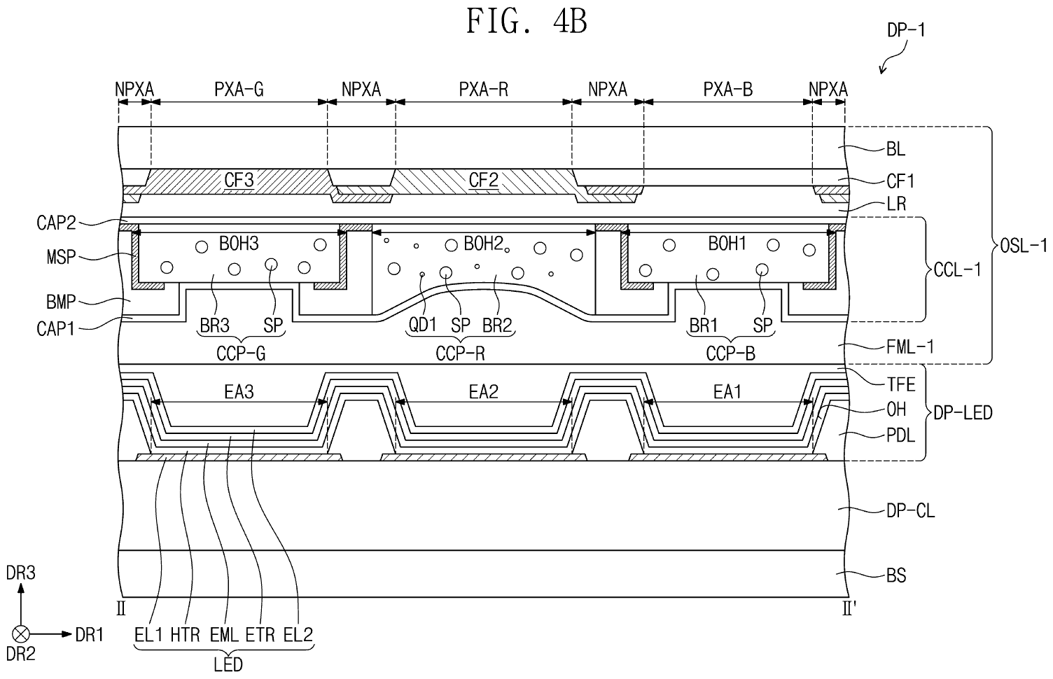

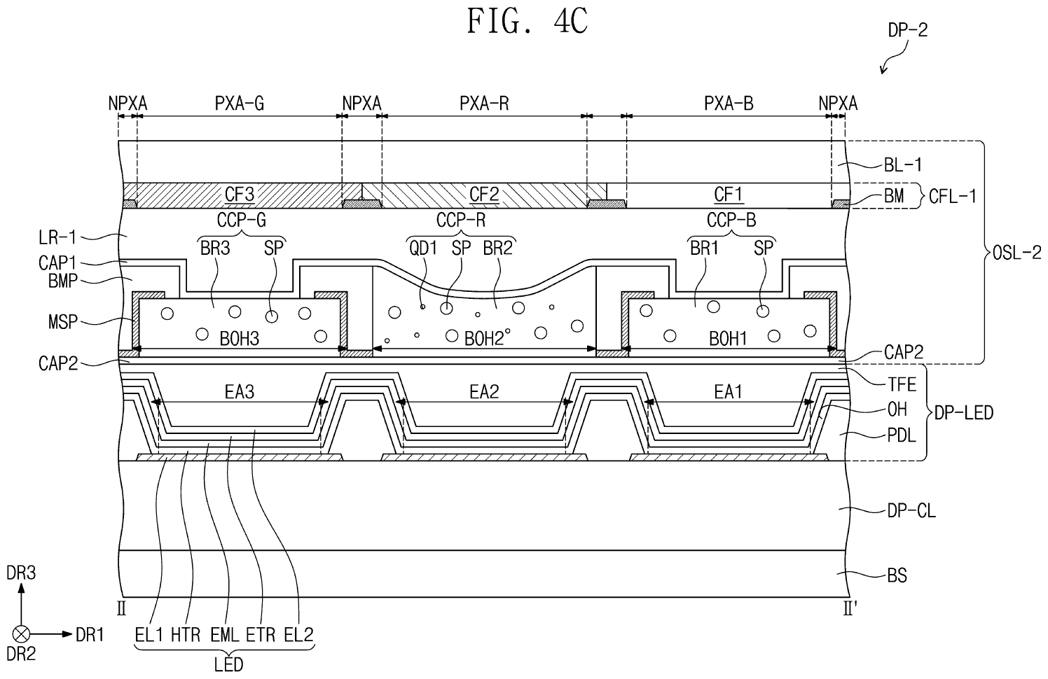

FIG. 2 is an enlarged plan view illustrating a portion of the display panel according to an embodiment of the disclosure. FIG. 3 is a schematic cross-sectional view illustrating a portion of the display panel according to an embodiment of the disclosure. FIGS. 4A to 4D are schematic cross-sectional views illustrating a portion of the display panel according to an embodiment of the disclosure. FIG. 3 schematically illustrates a cross-section corresponding to line I-I′ of FIG. 2. FIGS. 4A to 4D schematically illustrate a cross-section corresponding to line II-II′ of FIG. 2.

In FIG. 2, in the display panel DP (see FIG. 1A) according to an embodiment, an arrangement relationship between multiple pixel areas disposed on the display area DA is illustrated. In an embodiment of the disclosure, the pixel areas PXA-B, PXA-R, and PXA-G having a shape may be repeatedly arranged in the entire display area DA (see FIG. 1A).

Referring to FIG. 2, a peripheral area NPXA may be disposed around the first to third pixel areas PXA-B, PXA-R, and PXA-G. The peripheral area NPXA may set boundaries between the first to third pixels PXA-B, PXA-R, and PXA-G. The peripheral area NPXA may surround the first to third pixel areas PXA-B, PXA-R, and PXA-G. In an embodiment, one first pixel area PXA-B, one second pixel area PXA-R, and one third pixel area PXA-G, which are arranged side by side in a direction (for example, the first direction DR1) may form a group and be referred to as a “pixel area PXA-U”.

A structure that prevents colors between the first to third pixel areas PXA-B, PXA-R, PXA-G from being mixed, for example, a pixel defining layer PDL (see FIG. 3) or a bank BMP (see FIG. 3) may be disposed in the peripheral area NPXA. Two or more color filters described below may overlap each other in the third direction DR3 in the peripheral area NPXA.

As illustrated in FIG. 2, each of the first to third pixel areas PXA-B, PXA-R, and PXA-G may have a rectangular shape in a plan view. Each of the first to third pixel areas PXA-B, PXA-R, and PXA-G may have a rectangular shape having a short side extending in the first direction DR1 and a long side extending in the second direction DR2. The first to third pixel areas PXA-B, PXA-R, and PXA-G may be spaced apart from each other in the first direction DR1.

In FIG. 2, the first to third pixel areas PXA-B, PXA-R, and PXA-G, each having a rectangular shape, are illustrated, but the disclosure is not limited thereto. In another embodiment, a portion of the first to third pixel areas PXA-B, PXA-R, and PXA-G may have a polygonal shape (including a substantial polygonal shape), which is different from the rectangular shape. In an embodiment, each of the first to third pixels PXA-B, PXA-R, and PXA-G may have a rectangular shape (substantially rectangular shape) having rounded corner areas in a plan view.

One of the first to third pixels PXA-B, PXA-R, and PXA-G may provide blue light, another one of the first to third pixels PXA-B, PXA-R, and PXA-G may provide red light, and a remaining one of the first to third pixels PXA-B, PXA-R, and PXA-G may provide green light. In this embodiment, the first pixel area PXA-B may provide blue light, the second pixel area PXA-R may provide red light, and the third pixel area PXA-G may provide green light. The first pixel area PXA-B may emit light having an emission wavelength in a range of about 410 nm to about 480 nm, the second pixel area PXA-R may emit light having an emission wavelength in a range of about 620 nm to about 700 nm, and the third pixel area PXA-G may emit light having an emission wavelength in a range of about 520 nm to about 600 nm.

FIG. 2 illustrates that surface areas of the first to third pixel areas PXA-B, PXA-R, and PXA-G in a plan view are the same, but the disclosure is not limited thereto. For example, the surface area of each of the first to third pixel areas PXA-B, PXA-R, and PXA-G may be set according to the color of the emitted light. In the primary colors, the surface area of the pixel area that emits red light may be the largest, and the surface area of the pixel area that emits blue light may be the smallest. For example, the surface area of the second pixel area PXA-R, which emits red light, may be the largest, and the surface area of the first pixel area PXA-B, which emits blue light, may be the smallest.

A bank opening BOH corresponding to each pixel area PXA may be provided in the display area DA according to an embodiment. The bank opening BOH may be provided to correspond to each pixel area PXA so that multiple light control patterns CCP-B, CCP-R, and CCP-G (see FIG. 4A) described below may be disposed.

The bank opening BOH may include a first bank opening BOH1 corresponding to the first pixel area PXA-B, a second bank opening BOH2 corresponding to the second pixel area PXA-R, and a third bank opening BOH3 corresponding to the third pixel area PXA-G. Each of the first to third bank openings BOH1, BOH2, and BOH3 may have a rectangular shape in a plan view. Each of the first to third bank openings BOH1, BOH2, and BOH3 may have a rectangular shape having a short side extending in the first direction DR1 and a long side extending in the second direction DR2. The first to third bank opening BOH1, BOH2, and BOH3 may be spaced apart from each other in the first direction DR1.

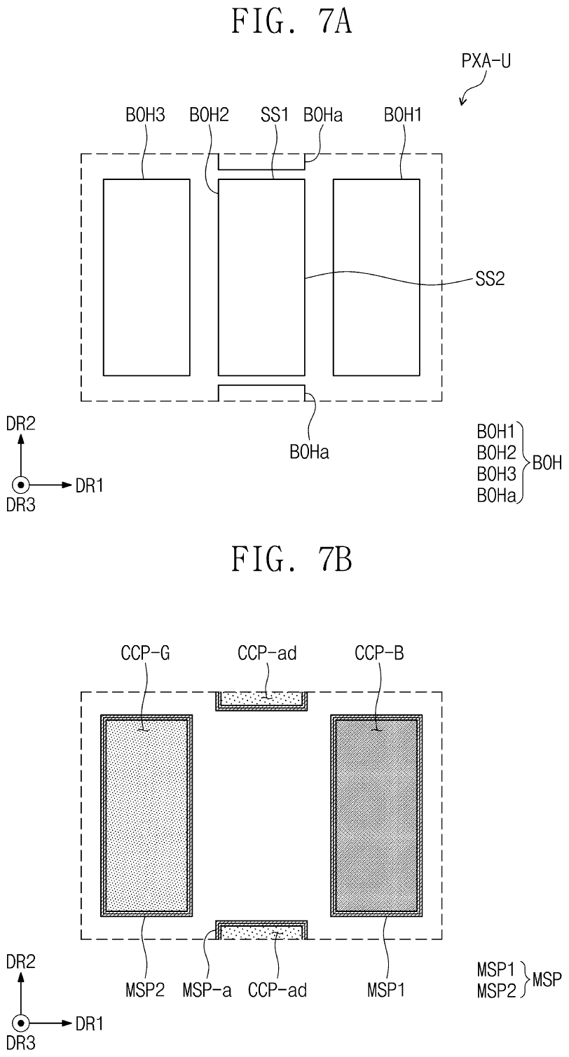

The bank opening BOH may include an additional bank opening BOHa provided adjacent to at least one short side of the pixel areas PXA. The additional bank opening BOHa may be provided adjacent to a short side of the second pixel area PXA-R. The additional bank opening BOHa may be provided so that an additional light control pattern CCP-ad (see FIG. 7B) described below may be disposed. The additional bank opening may be spaced apart from the second bank opening BOH2 in the second direction DR2.

Although not shown, a bank well area may be defined in the display area DA. The bank well area may be an area in which a bank wall is defined to prevent defects due to mis-dropping in a process of printing a portion of the light control patterns CCP-B, CCP-R, and CCP-G (see FIG. 4A) included in the light control layer CCL (see FIG. 4A) from occurring. For example, the bank well area may be an area in which the bank well defined by removing a portion of the bank BMP (see FIG. 4A) is defined.

Referring to FIG. 3, the display panel DP according to an embodiment may include a base substrate BS, a circuit element layer DP-CL disposed on the base substrate BS, and a display element layer DP-LED disposed on the circuit element layer DP-CL. In this specification, the base substrate BS, the circuit element layer DP-CL, and the display element layer DP-LED may be integrally referred to as a lower panel.

The base substrate BS may be a member providing a reference surface on which a configuration included in the circuit element layer DP-CL is disposed. In an embodiment, the base substrate BS may be a glass substrate, a metal substrate, or a polymer substrate. However, the disclosure is not limited thereto, and the base substrate BS may be an inorganic layer, a functional layer, or a composite material layer.

The base substrate BS may have a multilayer structure. For example, the base substrate BS may have a three-layer structure of a polymer resin layer, an adhesive layer, and a polymer resin layer. For example, the polymer resin layer may include a polyimide-based resin. For example, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In this specification, the “α-based” resin may mean a resin including “α” functional group.

The circuit element layer DP-CL may be disposed on the base substrate BS. The circuit element layer DP-CL may include a transistor T-D as a circuit element. As a drive circuit of the pixel PX (see FIG. 1A) is designed, the configuration of the circuit element layer DP-CL may be changed, and one transistor T-D is illustrated in FIG. 3 according to an embodiment. An arrangement relationship between an active A-D, a source S-D, a drain D-D, and a gate G-D that constitute the transistor T-D is illustrated according to an embodiment. The active A-D, the source S-D, and the drain D-D may be regions that are distinguished from each other depending on a doping concentration or conductivity of a semiconductor pattern.

The circuit element layer DP-CL may include a lower buffer layer BRL, a first insulating layer 10, a second insulating layer 20, and a third insulating layer 30 disposed on the base substrate BS. For example, the lower buffer layer BRL, the first insulating layer 10 and the second insulating layer 20 may be inorganic layers, and the third insulating layer 30 may be an organic layer.

The display element layer DP-LED may include a light emitting element LED as a display clement. The light emitting element LED may produce source light. In an embodiment, the source light may be white or blue light. In an embodiment, the display element layer DP-LED may include an organic light emitting diode as a light emitting element. For example, an emission layer EML included in the light emitting element LED may include an organic light emitting material as a light emitting material.

The light emitting element LED may include a first electrode EL1, a second electrode EL2, and an emission layer EML disposed between the first electrode EL1 and the second electrode EL2. In this embodiment, the display element layer DP-LED may include an organic light emitting diode as a light emitting element. In another embodiment of the disclosure, the light emitting element may include a quantum dot light emitting diode. For example, the emission layer EML included in the light emitting element LED may include an organic light emitting material as a light emitting material, or the emission layer EML may include quantum dots as a light emitting material. In another embodiment, the display element layer DP-LED may include a micro light emitting element described below as a light emitting element. The micro light emitting element may include, for example, a micro LED element and/or nano LED element. The micro light emitting element may be a light emitting element having a micro or nano-scale size and including an active layer disposed between multiple semiconductor layers.

The first electrode EL1 may be disposed on the third insulating layer 30. The first electrode EL1 may be directly or indirectly connected to the transistor T-D, and in FIG. 3, a connection structure of the first electrode EL1 and the transistor T-D is not illustrated.

The display element layer DP-LED may include a pixel defining layer PDL. For example, the pixel defining layer PDL may be an organic layer. A light emitting opening may be defined in the pixel defining layer PDL. The light emitting opening of the pixel defining layer PDL may expose at least a portion of the first electrode EL1 in a plan view. In an embodiment, a second emission area EA2 may be defined by the light emitting openings OH.

A hole control layer HTR, an emission layer EML, and an electron control layer ETR may overlap at least pixel area PXA-R in the third direction DR3. Each of the hole control layer HTR, the emission layer EML, the electron control layer ETR, and the second electrode EL2 may be commonly disposed in the first to third pixel areas PXA-B, PXA-R, and PXA-G (see FIG. 4A). Each of the hole control layers HTR, the emission layer EML, the electron control layer ETR, and the second electrode EL2 in first to third pixel areas PXA-B, PXA-R, and PXA-G (see FIG. 4A) may have an integrated shape. However, the disclosure is not limited thereto. For example, at least one of the hole control layer HTR, the emission layer EML, and the electron control layer ETR may be separated for each of the first to third pixel areas PXA-B, PXA-R, and PXA-G (see 4A). In an embodiment, the emission layer EML may be patterned in the light emitting opening and may be separated for each of the first to third pixel areas PXA-B, PXA-R, and PXA-G (see FIG. 4A).

The hole control layer HTR may include a hole transport layer and may further include a hole injection layer.

The emission layer EML may produce third light that is the source light. The emission layer EML may produce blue light. The blue light may have a wavelength in a range of about 410 nm to about 480 nm. A light emitting spectrum of the blue light may have a maximum peak in a wavelength range of about 440 nm to about 460 nm.

The electron control layer ETR may include an electron transport layer and may further include an electron injection layer.

The display element layer DP-LED may include a thin film encapsulation layer TFE that protects the second electrode EL2. The thin film encapsulation layer TFE may include an organic material or an inorganic material. The thin film encapsulation layer TFE may have a multilayer structure in which an inorganic layer and an organic layer are repeatedly disposed. In an embodiment, the thin film encapsulation layer TFE may include a first encapsulation inorganic layer IOL1, an organic layer OL, and a second encapsulation inorganic layer IOL2. The first and second encapsulation inorganic layers IOL1/IOL2 may protect the light emitting element LED from external moisture, and the encapsulation organic layer OL may prevent defects of the light emitting element LED dent by foreign substances introduced during the manufacturing process from occurring. Although not shown, the display panel DP may further include a refractive index control layer for improving emitting efficiency on the thin film encapsulation layer TFE.

As illustrated in FIG. 3, an optical structure layer OSL may be disposed on the thin film encapsulation layer TFE. The optical structure layer OSL may include a light control layer CCL, a filling layer FML, a color filter layer CFL, and a base layer BL. In this specification, the optical structure layer OSL may be referred to as an upper panel.

The light control layer CCL may be disposed on the display element layer DP-LED including the light emitting element LED. The light control layer CCL may include a bank BMP, a second light control pattern CCP-R, a first barrier layer CAP1, and a second barrier layer CAP2.

The bank BMP may include a base resin and an additive. The base resin may generally be made of a resin composition that may be referred to as a binder. The additive may include a coupling agent and/or a photoinitiator. The additive may further include a dispersing agent.

In an embodiment, the bank BMP included in the light control layer CCL may be optically transparent. The bank BMP may include an optically transparent material. The base resin included in the bank BMP may be optically transparent. The bank BMP may include a material having a transmittance greater than or equal to about 85% in a visible light range. The bank BMP may not include a separate coloring agent. The bank BMP may include a black dye and a black pigment, which are mixed with the base resin. In an embodiment, the bank BMP may not include a light blocking material having a black color such as carbon black or a pigment or dye having a blue color.

The bank BMP may include a bank opening BOH2 corresponding to the light emitting opening OH. In a plan view, the bank opening BOH2 may overlap the light emitting opening OH and have an area greater than an area of the light emitting opening OH. For example, the bank opening BOH2 may have a greater area compared to the emission area EA2 defined by the light emitting opening OH. In this specification, the “corresponding” means that two configurations overlap each other in a thickness direction DR3 of the display panel DP, but is not limited to the same area.

A second light control pattern CCP-R may be disposed inside the bank opening BOH2. The second light control pattern CCP-R may change optical properties of the source light.

The second light control pattern CCP-R may include a first quantum dot QD1 for changing the optical properties of the source light. The second light control pattern CCP-R may include a first quantum dot QD1 that converts the source light into light having a different wavelength. In the second light control pattern CCP-R in the second pixel area PXA-R, the first quantum dot QD1 may convert the source light into red light.

In this specification, the “quantum dot” may be a crystal of a semiconductor compound. The quantum dot may emit light having various emission wavelengths depending on a size of the crystal. The quantum dot may emit light having various emission wavelengths by adjusting an element ratio in the quantum dot compound.

A diameter of the quantum dot may be, for example, in a range of about 1 nm to 10 nm.

The quantum dot may be synthesized by a wet chemical process, a metal organic chemical vapor deposition process, a molecular beam epitaxy process, or a process similar thereto.

The wet chemical process may be a method for growing quantum dot particle crystals after mixing an organic solvent and a precursor material. In case that a crystal is grown, the organic solvent may naturally serve as a dispersing agent that is coordinated on a surface of the quantum dot and may adjust the growth of the crystal. Therefore, the wet chemical process may be more readily performed than the metal organic chemical vapor deposition (MOCVD) or the molecular beam epitaxy (MBE), and the growth of the quantum dot particles may be controlled with a low cost process.

A core of the quantum dot may include a Group II-VI compound, a Group III-V compound, a Group III-VI compound, a Group I-III-VI compound, a Group IV-VI compound, a Group IV compound, a Group IV compound, or a combination thereof.

The Group II-VI compound may be selected from the group consisting of a binary element compound such as CdSe, CdTe, ZnS, ZnSe, ZnTe, ZnO, HgS, HgSe, HgTe, MgSe, MgS, and a mixture thereof, a ternary element compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary element compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI semiconductor compound may further include a Group I metal and/or a Group IV element. The Group I-II-VI compound may be selected from CuSnS or CuZnS, and ZnSnS may be selected for the Group II-IV-VI compound. The Group I-II-IV-VI compound may be selected from a quaternary element compound such as Cu₂ZnS₂, Cu₂ZnSnS₄, Cu₂SnSnSe₄, Ag₂ZnS₂, and a mixture thereof.

The Group III-VI compound may include a binary element compound such as In₂S₃, In₂Se₃, etc., a ternary element compound such as InGaS₃, InGaSe₃, etc., or a combination thereof.

The Group I-III-VI compound may be selected from a ternary element compound such as AgInS, AgIn S₂, CuInS, CuInS₂, AgGaS₂, CuGaS₂, CuGaO₂, AgGaO₂, AgAlO₂, and a mixture thereof or a quaternary element compound such as AgInGaS₂, CuInGaS₂, etc.

The Group III-V compound may be selected from the group consisting of a binary element compound such as GaN, GaP, GaAs, GaSb, AlN, AlP, AlAs, AlSb, InN, InP, InAs, InSb, and a mixture thereof, a ternary element compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, InZnP may be selected for the Group III-II-V compound.

The Group IV-VI compound may be selected from the group consisting of a binary element compound such as SnS, SnSe, SnTe, PbS, PbSe, PbTe, and a mixture thereof, a ternary element compound such as SnSeS, SnSeTe, SnSTe, PbSeS, PbSeTe, PbSTe, SnPbS, SnPbSe, SnPbTe, and a mixture thereof, and a quaternary element compound such as SnPbSSe, SnPbSeTe, SnPbSTe, and a mixture thereof.

Examples of the Group II-IV-V semiconductor compound may be a ternary element compound such as ZnSnP, ZnSnP₂, ZnSnAS₂, ZnGeP₂, ZnGeAS₂, CdSnP₂, CdGeP₂, and a mixture thereof.

The Group IV element may be selected from the group consisting of Si, Ge, and a mixture thereof. The Group IV compound may be a binary element compound such as SiC, SiGe, and a mixture thereof.

Each element included in multi-element compounds such as a binary element compound, a ternary element compound, and a quaternary element compound may be present in particles at a uniform concentration or non-uniform concentration. For example, the chemical formula may indicate the type of elements included in the compound, and the element ratio in the compounds may be different from each other. For example, AgInGaS₂ may mean AgInxGa₁₋ₓS₂ (x is a real number between 0 and 1).

Here, the binary element compounds, the ternary element compounds, and the quaternary element compounds may exist in a particle at a uniform concentration or exist in a particle in a state in which concentration distribution is partitioned into partially different states. In an embodiment, the quantum dot may have a core/shell structure in which a quantum dot surrounds another quantum dot. In the core/shell structure, the concentration of the element in the shell may be gradient to be gradually lowered to the core.

In some embodiments, the quantum dot may have a core-shell structure, which includes a core including the above-described nano crystal and a shell surrounding the core. The shell of the quantum dot may serve as a protection layer that prevents the core from being chemically changed to maintain the semiconductor characteristics and/or may serve as a filling layer for imparting electrophoretic characteristics to the quantum dot. The shell may be a single layer or a multi-layer. For example, the shell of the quantum dot may include a metal oxide, a nonmetal oxide, a semiconductor compound, or a combination thereof.

For example, a metal oxide or a nonmetal oxide may include a binary element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like or a ternary element compound such as MgAl₂O₄, CoFe₂O₄, NiFe₂O₄, CoMn₂O₄, and the like, but the disclosure is not limited thereto.

For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the disclosure is not limited thereto.

The quantum dot may have a full width of half maximum (FWHM) of an emission wavelength spectrum less than or equal to about 45 nm. For example, the quantum dot may have a full width of half maximum (FWHM) of an emission wavelength spectrum less than or equal to about 40. For example, the quantum dot may have a full width of half maximum (FWHM) of an emission wavelength spectrum less than or equal to about 30 nm. In this range, color purity and color reproducibility may be improved. Also, light emitted through the quantum dot may be emitted in all directions to improve an optical viewing angle.

The quantum dot may have a shape that is generally used in the art and is not specifically limited in shape. In an embodiment, the quantum dot may have a spherical shape, a pyramidal shape, a multi-arm shape, a cubic nanoparticle shape, a nanotube shape, a nanowire shape, a nanofiber shape, a nanoplate particle shape, or the like.

By adjusting a size of the quantum dot, or adjusting an element ratio within the quantum dot compound to adjust an energy band gap, quantum dots may obtain light having various wavelengths from the quantum dot emission layer. Thus, quantum dots (in which quantum dots having different sizes are used, or an element ratio within the quantum dot compound is changed) may be used to implement a light emitting element that emits multiple wavelengths. For example, the adjustment of the size of the quantum dot or the adjustment of the element ratio within the quantum dot compound may be selected to emit the red, green and/or blue light. In an embodiment, the quantum dots may be configured to emit white light by combining light having various colors.

In an embodiment, the first quantum dot QD1 included in the second light control pattern CCP-R disposed in the second pixel area PXA-R may emit red light. As a particle size of the quantum dot decreases, light having a short wavelength range may be emitted. For example, the particle size of the quantum dots that emit green light from the quantum dot having a same core may be less than the particle size of the quantum dots that emit red light. For example, the particle size of the quantum dots that emit blue light from the quantum dot having a same core may be less than the particle size of the quantum dots that emit green light. However, the disclosure is not limited thereto, and the particle size may be adjusted depending on the material of the shell and the thickness of the shell even in the quantum dots having a same core.

Quantum dots emitting different colors may have different core materials.

The second light control pattern CCP-R may further include a scatterer SP. The second light control pattern CCP-R may include a first quantum dot QD1 that converts blue light into red light, and a scatterer SP that scatters light.

The scatterer SP may be an inorganic particle. For example, the scatterer SP may include at least one of TiO₂, ZnO, Al₂O₃, SiO₂, hollow silica, and a mixture thereof.

The second light control pattern CCP-R may include a second base resin BR2 that disperses the first quantum dot QD1 and the scatterer SP. The second base resin BR2 may be made of a resin compound that is generally referred to as a binder in which the first quantum dot QD1 and the scatterer SP are dispersed. For example, the second base resin BR2 may include at least one of an acrylic-based resin, a urethane-based resin, and a silicon-based resin, and an epoxy-based resin. The second base resin BR2 may be a transparent resin. The second base resin BR2 may be a resin selected to perform an inkjet process.

In this embodiment, the second light control pattern CCP-R may be formed by an inkjet process. The second light control pattern CCP-R may be formed through a curing process after a composition of a liquid is provided in the second bank opening BOH2. The compositions polymerized by a thermal curing process or an optical curing process may be reduced in volume after the curing.

The light control layer CCL may include a first barrier layer CAP1 disposed on a surface of the second light control pattern CCP-R. The first barrier layer CAP1 may prevent moisture and/or oxygen (hereinafter, referred to as ‘moisture/oxygen’) from being penetrated and adjust a refractive index to improve optical properties of the optical structure layer OSL. The first barrier layer CAP1 may be disposed on an upper surface or a lower surface of the second light control pattern CCP-R to prevent the second light control pattern CCP-R, for example, the quantum dots in the second light control pattern CCP-R, from being exposed to the moisture/oxygen. The first barrier layer CAP1 may also protect the second light control pattern CCP-R from an external impact.

In an embodiment, the first barrier layer CAP1 may be spaced apart from the display element layer DP-LED with the second light control pattern CCP-R interposed between the first barrier layer CAP1 and the display element layer DP-LED. For example, the first barrier layer CAP1 may be disposed on a top surface of the second light control pattern CCP-R. In an embodiment, the light control layer CCL may include a second barrier layer CAP2 disposed between the second light control pattern CCP-R and the display element layer DP-L. The first barrier layer CAP1 may cover a top surface of the second light control pattern CCP-R adjacent to the filling layer FML, and the second barrier layer CAP2 may cover a bottom surface of the second light control pattern CCP-R adjacent to the display element layer DP-LED. In this specification, the “top surface” may be a surface disposed at an upper portion based on the third direction DR3, and the “bottom surface” may be a surface disposed at a lower portion based on the third direction DR3.

In an embodiment, the first barrier layer CAP1 and the second barrier layer CAP2 may each cover a surface of the bank BMP as well as the second light control pattern CCP-R.

The first barrier layer CAP1 may cover a surface of the bank BMP and the second light control pattern CCP-R, which are adjacent to the filling layer FML. The first barrier layer CAP1 may be disposed below (e.g., directly below) the filling layer FML. The second barrier layer CAP2 may be disposed above (e.g., directly above) the thin film encapsulation layer TFE. The light control layer CCL may be disposed on the display element layer DP-LED and the thin film encapsulation layer TFE with the second barrier layer CAP2 interposed between the light control layer CCL and the display element layer DP-LED. The light control patterns CCP-B, CCP-R, and CCP-G of the light control layer CCL may be formed on the second barrier layer CAP2 disposed on the thin film encapsulation layer TFE through a continuous process.

Each of the first barrier layer CAP1 and the second barrier layer CAP2 may include an inorganic material. In the display panel DP according to an embodiment, the first barrier layer CAP1 may include silicon oxynitride (SiON). Both the first barrier layer CAP1 and the second barrier layer CAP2 may include silicon oxynitride. However, the disclosure is not limited thereto, and each of the first barrier layer CAP1 and the second barrier layer CAP2 may include silicon oxide (SIO_{X}) or silicone knight (SIN_{X}). In an embodiment, the first barrier layer CAP1 disposed on the upper portion of the second light control pattern CCP-R may include silicon oxynitride, and the second barrier layer CAP2 disposed on the lower portion of the second light control pattern CCP-R may include silicone oxide.

A color filter layer CFL may be disposed on the light control layer CCL. The color filter layer CFL may include at least one color filter. The color filter may transmit light having a corresponding wavelength range and block light other than the corresponding wavelength range. The second color filter CF2 corresponding to the second pixel area PXA-R may transmit red light and block green light and blue light.

The second color filter CF2 may include a base resin and a dye and/or pigment dispersed in the base resin. The base resin may be a medium in which the dye and/or pigment are dispersed. In general, the base resin may include various resin compositions that are called binders.

The second color filter CF2 may have a uniform thickness in the second pixel area PXA-R. The light converted from the source light that is blue light into the red light through the second light control pattern CCP-R may be provided to the outside with uniform luminance in the second pixel area PXA-R.

The optical structure layer OSL may further include a filling layer FML disposed between the light control layer CCL and the color filter layer CFL. In an embodiment, the filling layer FML may be filled between the light control layer CCL and the color filter layer CFL. The filling layer FML may be disposed on (e.g., directly on) the first barrier layer CAP1, and the color filter layer CFL may be disposed on (e.g., directly on) the filling layer FML. A bottom surface of the filling layer FML may be in contact with a top surface of the first barrier layer CAP1, and a top surface of the filling layer FML may be in contact with bottom surfaces of the color filters CF1, CF2, and CF3 of the color filter layer CFL.

The filling layer FML may function a buffer between the light control layer CCL and the color filter layer CFL. In an embodiment, the filling layer FML may perform impact absorption, etc., and may increase in strength of the display panel DP. The filling layer FML may be made of a filling resin such as a polymer resin. For example, the filling layer FML may be a filling layer resin including an acrylic resin or an epoxy resin.

The filling layer FML may be disposed between the light control layer CCL and the color filter layer CFL to improve light extraction efficiency or prevent the reflected light from being incident into the light control layer CCL. The filling layer FML may be a layer having a small refractive index compared to adjacent layers.

In an embodiment, the display panel DP may further include a base layer BL disposed on the color filter layer CFL. The base layer BL may be a member that provides a reference surface on which the color filter layer CFL, the filling layer FML, and the light control layer CCL are disposed. The base layer BL may include a glass substrate, a metal substrate, a plastic substrate, and/or the like. However, the disclosure is not limited thereto. For example, the base layer BL may be an inorganic layer, an organic layer, or a composite layer. In another embodiment, the base layer BL may be omitted, unlike that described above.

Although not shown, an anti-reflection layer may be disposed on the base layer BL. The anti-reflection layer may be a layer that reduces reflectance of external light incident from the outside. The anti-reflection layer may be a layer that selectively transmits light emitted from the display panel DP. In an embodiment, the anti-reflection layer may be a single layer including a dye and/or pigment dispersed in a base resin. The anti-reflection layer may be provided as continuous one layer that overlaps the entire first to third pixel areas PXA-B, PXA-R, and PXA-G (sec FIG. 4A).

The anti-reflection layer may not include a polarization layer. Thus, the light that passes through the anti-reflection layer and is incident toward the display element layer DP-LED may be light that is not polarized. The display element layer DP-LED may receive the non-polarized light from an upper side of the anti-reflection layer.

Referring to FIG. 4A, the display panel DP may include a base substrate BS and a circuit element layer DP-CL disposed on the base substrate BS. The circuit element layer DP-CL may be disposed on the base substrate BS. The circuit element layer DP-CL may include an insulating layer, a semiconductor pattern, a conductive pattern, and a signal line. The insulating layer, the semiconductor layer, and the conductive layer may be disposed on the base substrate BS through coating, deposition, etc., and the insulating layer, the semiconductor layer, and the conductive layer may be selectively patterned through multiple photolithography processes. Thereafter, the semiconductor pattern, the conductive pattern, and the signal line included in the circuit element layer DP-CL may be formed. In an embodiment, the circuit element layer DP-CL may include a transistor, a buffer layer, and multiple insulating layers.

The light emitting element LED according to an embodiment may include a first electrode EL1, a second electrode EL2 facing the first electrode EL1, and an emission layer EML disposed between the first electrode EL1 and the second electrode EL2. The emission layer EML included in the light emitting element LED may include an organic light emitting material as a light emitting material or may include a quantum dot. The light emitting element LED may further include a hole control layer HTR and an electron control layer ETR. Although not shown, the light emitting element LED may further include a capping layer (not shown) disposed on the second electrode EL2.

The pixel defining layer PDL may be disposed on the circuit element layer DP-CL and cover a portion of the first electrode EL1. A light emitting opening may be defined in the pixel defining layer PDL. The light emitting opening of the pixel defining layer PDL may expose at least a portion of the first electrode EL1. In an embodiment, the emission areas EA1, EA2, and EA3 may be defined to correspond to a partial area of the first electrode EL1 exposed by the light emitting openings OH.

The display element layer DP-LED may include a first emission area EA1, a second emission area EA2, and a third emission area EA3. The first emission area EA1, the second emission area EA2, and the third emission area EA3 may be areas that are divided by the pixel defining layer PDL. The first emission area EA1, the second emission area EA2, and the third emission area EA3 may correspond to the first pixel area PXA-B, the second pixel area PXA-R, and the third pixel area PXA-G, respectively.

The emission areas EA1, EA2, and EA3 may overlap the pixel area PXA-B, PXA-R, and PXA-G in a plan view. In a plan view, an area of each of pixel areas PXA-B, PXA-R, and PXA-G, which are divided into the color filters CF1, CF2, and CF3 and an area of each of the emission areas EA1, EA2, and EA3 that are divided by the pixel defining layer PDL may be substantially the same.

In the light emitting element LED, the first electrode EL1 may be disposed on the circuit element layer DP-CL. The first electrode EL1 may be an anode or a cathode. For example, the first electrode EL1 may be a pixel electrode. The first electrode EL1 may be a transmissive electrode, a transflective electrode, or a reflective electrode.

The hole control layer HTR may be disposed between the first electrode EL1 and the emission layer EML. The hole control layer HTR may include at least one of a hole injection layer, a hole transport layer, and an electron stop layer. The hole control layer HTR may be disposed as a common layer over the emission areas EA1, EA2, EA3 and EA3 and the entire pixel defining layer PDL, which divides the emission areas EA1, EA2, EA3 and EA3 into each other. However, the disclosure is not limited thereto, and the hole control layer HTR may be patterned to be separated so as to correspond to the emission areas EA1, EA2, EA3 and EA3, respectively.

The emission layer EML may be disposed on the hole control layer HTR. In an embodiment, the emission layer EML may be provided as a common layer over the emission areas EA1, EA2, and EA3 and the entire pixel defining layer PDL that divides the emission areas EA1, EA2, and EA3 into each other. In an embodiment, the emission layer EML may emit blue light. The emission layer EML may overlap the entire hole control layer HTR and electron control layer ETR in a plan view.

However, the disclosure is not limited thereto, and in another embodiment, the emission layer EML may be disposed in the light emitting opening OH. For example, the emission layer EML may be separated to correspond to the emission areas EA1, EA2, and EA3 that are divided by the pixel defining layer PDL. All the emission layer EML disposed to correspond to the emission areas EA1, EA2, and EA3 may emit blue light or emit light having different wavelength ranges.

The emission layer EML may have a structure formed of a material, a structure formed of different materials, or a structure including multiple layers formed of different materials. The emission layer EML may include a fluorescent or phosphorus material. In the light emitting element according to an embodiment, the emission layer EML may include an organic light emitting material, a metal organic complex, or a quantum dot as a light emitting material. In FIGS. 3 and 4A, the light emitting element EML including one emission layer EML is illustrated according to an embodiment, but the disclosure is not limited thereto, and in another embodiment, each of the light emitting elements LED may include multiple light emitting stacks including at least one emission layer.

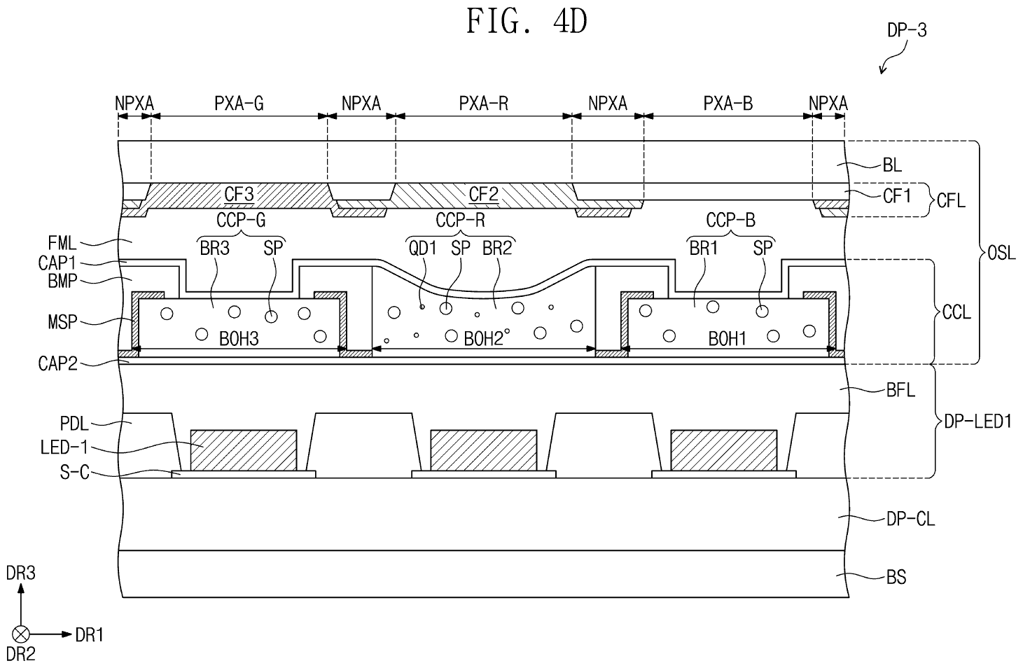

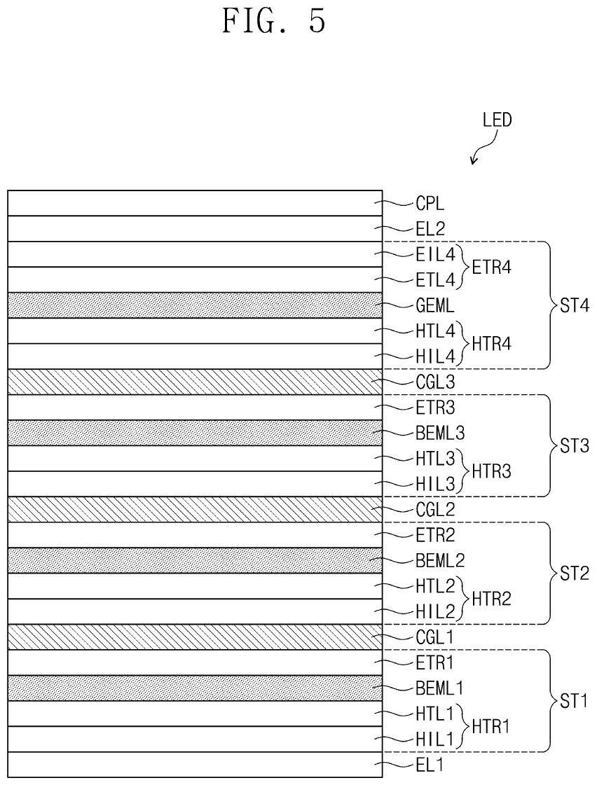

FIG. 5 is a schematic cross-sectional view of the light emitting element according to an embodiment of the disclosure. In FIG. 5, unlike the light emitting element illustrated in FIGS. 3 and 4A, a light emitting element LED including multiple light emitting stacks ST1, ST2, ST3, ST4 is illustrated according to an embodiment.

Referring to FIG. 5, the light emitting element LED according to an embodiment may include a first electrode EL1, a second electrode EL2 facing the first electrode EL1, and first to fourth light emitting stacks ST1, ST2, ST3, and ST4 disposed between the first electrode EL1 and the second electrode EL2. FIG. 5 illustrates that the light emitting element LED includes four light emitting stacks, but the disclosure is not limited thereto, and the number of light emitting stacks included in the light emitting element LED may be less than four.

The light emitting element LED may include first to third charge production layers CGL1, CGL2, and CGL3 disposed between adjacent ones of the first to fourth light emitting stacks ST1, ST2, ST3, and ST4.

Each of the first to third charge production layers CGL1, CGL2, and CGL3 may generate charges (electrons and holes) by forming a complex through an oxidation-reduction reaction in case that a voltage is applied. Thereafter, the first to third charge production layers CGL1, CGL2, and CGL3 may provide the produced charges to the adjacent stacks ST1, ST2, ST3, and ST4, respectively. The first to third charge production layers CGL1, CGL2, and CGL3 may improve efficiency of current generated in the adjacent stacks ST1, ST2, ST3, and ST4 and may adjust balance of the charges between the adjacent stacks ST1, ST2, ST3, and ST4.

Each of the first to third charge production layers CGL1, CGL2, and CGL3 may include an N-type layer and a P-type layer. The first to third charge production layers CGL1, CGL2, and CGL3 may have a structure in which the N-type layer and the P-type layer are bonded to each other. However, the disclosure is not limited thereto, and each of the first to third charge production layers CGL1, CGL2, and CGL3 may include only one of the N-type layer and the P-type layer. The N-type layer may be a charge production layer that provides an electron to the adjacent stack. The N-type layer may be a layer in which an n-dopant is doped in the base material. The P-type layer may be a charge production layer that provides a hole to the adjacent stack.

In an embodiment, a thickness of each of the first to third charge production layers CGL1, CGL2, and CGL3 may be in a range of about 1 angstrom (å) to about 150 angstrom (å). A concentration of an n-dopant doped in the first to third charge production layers CGL1, CGL2, and CGL3 may be in a range of about 0.1% to about 3%. For example, a concentration of an n-dopant doped in the first to third charge production layers CGL1, CGL2, and CGL3 may be less than about 1%. If the concentration is less than about 0.1%, effects of the first to third charge production layers CGL1, CGL2, and CGL3 may reduce. If the concentration is greater than about 3%, light efficiency of the light emitting element LED may be deteriorated. Each of the first to third charge production layers CGL1, CGL2, and CGL3 may include an arylamine-based organic compound, a metal, metal oxide, carbide, fluoride, or a mixture thereof. For example, the arylamine-based organic compound may include α-NPD, 2-TNATA, TDATA, MTDATA, sprio-TAD, or sprio-NPB. The metal may include cesium (CS), molybdenum (MO), vanadium (V), titanium (Ti), tungsten (W), barium (BA), or lithium (Li). The metal oxide, the carbide, and the fluoride may include Re₂O₇, MoO₃, V₂O₅, WO₃, TiO₂, Cs₂CO₃, BaF, LiF, or CsF. However, the material of the first to third charge production layers CGL1, CGL2, and CGL3 is not limited to the above examples.

Each of the first to fourth light emitting stacks ST1, ST2, ST3, and ST4 may include an emission layer. The first light emitting stack ST1 may include a first emission layer BEML1, the second light emitting stack ST2 may include a second emission layer BEML2, the third light emitting stack ST3 may include a third emission layer BEML3, and the fourth light emitting stack ST4 may include a fourth emission layer GEML. Some of the emission layers included in the first to fourth light emitting stacks ST1, ST2, ST3, and ST4 may emit substantially a same color light, and some may emit different color light from each other.

In an embodiment, the first to third emission layers BEML1, BEML2, and BEML3 of the first to third light emitting stacks ST1, ST2, and ST3 may emit substantially a same first color light. For example, the first color light may be the blue light, which is described above. A wavelength range of light emitted from the first to third emission layers BEML1, BEML2, and BEML3 may be in a range of about 420 nm to about 480 nm.

The fourth emission layer GEML of the fourth light emitting stack ST4 may emit second color light, which is different from the first color light. For example, the second color light may be the green light. The wavelength range of light emitted from the fourth emission layer GEML may be in a range of about 520 nm to about 600 nm.

The light emitting element LED may emit light in a direction from the first electrode EL1 toward the second electrode EL2. In the light emitting element LED according to an embodiment, each of the light emitting stacks ST1, ST2, ST3, and ST4 may include hole transport regions HTR1, HTR2, HTR3, and HTR4 and electron transport regions ETR1, ETR2, ETR3, and ETR4. The holes provided from the hole transport region HTR1, HTR2, HTR3, and HTR4 or the charge production layers CGL1, CGL2, and CGL3 may be transmitted to the emission layer. The electron transport regions ETR1, ETR2, ETR3, and ETR4 may transmit electrons provided from the second electrode EL2 or the charge production layers CGL1, CGL2, and CGL3 to the emission layer.

The light emitting element LED may have a structure, in which the hole transport regions HTR1, HTR2, HTR3, and HTR4 are disposed below the emission layers BEML1, BEML2, BEML3, and GEML included in the light emitting stacks ST1, ST2, ST3, and ST4, and the electron transport region ETR1, ETR2, ETR3, and ETR4 are disposed above the emission layers BEML1, BEML2, BEML3, and GEML included in the light emitting stacks ST1, ST2, ST3, and ST4 based on the direction in which the light is emitted, according to an embodiment. For example, the light emitting element LED according to an embodiment may have a normal element structure, but the disclosure is not limited thereto. For example, the light emitting element LED may have an inverted element structure, in which the electron transport regions ETR1, ETR2, ETR3, and ETR4 are disposed below the emission layers BEML1, BEML2, BEML3, and GEML included in the light emitting stacks ST1, ST2, ST3, and ST4, and the hole transport regions HTR1, HTR2, HTR3, and HTR4 are disposed above the emission layers BEML1, BEML2, BEML3, and GEML included in the light emitting stacks ST1, ST2, ST3, and ST4 based on the direction in which the light is emitted.

Each of the hole transportation regions HTR1, HTR2, HTR3, and HTR4 may include hole injection layers HIL1, HIL2, HIL3, and HIL4 and hole transport layers HTL1, HTL2, HTL1, and HTL2 disposed on the hole injection layer HIL1, HIL2, HIL3, and HIL4, respectively. The hole transport layers HTL1, HTL2, HTL3, and HTL4 may be in contact with the bottom surface of the emission layer. However, the disclosure is not limited thereto, and the hole transport regions HTR1, HTR2, HTR3, and HTR4 may further include a hole-side additional layer disposed on the hole transport layers HTL1, HTL2, HTL3, and HTL4. The hole-side additional layer may include at least one of a hole buffer layer, an emission auxiliary layer, and an electron stop layer. The hole buffer layer may be a layer that improves emission efficiency by compensating a resonant distance according to a wavelength of light emitted from the emission layer. The electron stop layer may be a layer that prevents electrons from being injected from the electron transport region to the hole transport region.

The electron transport regions ETR1, ETR2, ETR3, and ETR4 may include an electron transport layer. The electron transport regions ETR1, ETR2, ETR3, and ETR4 may further include an electron injection layer disposed on the electron transport layer. For example, the fourth electron transport region ETR4 included in the fourth light emitting stack ST4 may further include the fourth electron injection layer EIL4 disposed on the fourth electron transport layer ETL4. The electron transport regions ETR1, ETR2, ETR3, and ETR4 may further include an electron-side additional layer disposed between the electron transport and the emission layers. The electron-side additional layer may include at least one of the electron buffer layer and the hole stop layer.

In the light emitting element LED according to an embodiment, the first electrode EL1 may be a reflective electrode. For example, the first electrode EL1 may include Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture thereof (e.g., mixture of Ag and Mg), which have high reflectivity. In an embodiment, the first electrode EL1 may have a structure of multiple layers including a reflective layer made of the above-described material and a transparent conductive layer made of indium tin oxide (ITO), indium zinc oxide (IZO), zinc oxide (ZnO), or indium tin zinc oxide (ITZO). For example, the first electrode EL1 may have a two-layer structure of ITO/AG or a three-layer structure of ITO/Ag/ITO. However, the disclosure is not limited thereto, and the first electrode EL1 may include the above-described metal materials, a combination of two or more metal materials of the above-described metal materials, or an oxide of the above-described metal materials. A thickness of the first electrode EL1 may be in a range of about 70 nm to about 1000 nm. For example, a thickness of the first electrode EL1 may be in a range of about 100 nm to about 300 nm.

In the light emitting element LED according to an embodiment, each of the hole transport regions HTR1, HTR2, HTR3, and HTR4 may have a layer made of a material, a layer made of different materials, or a multi-layer structure including layers made of different materials.

Each of the hole transport regions HTR1, HTR2, HTR3, and HTR4 may be formed by using various methods such as a vacuum deposition method, a spin coating method, a casting method, a Langmuir-Blodgett (LB) method, an inject printing method, a laser printing method, and a laser induced thermal imaging (LITI) method.

Each of the hole transport region HTR1, HTR2, HTR3, and HTR4 may include a phthalocyanine compound such as copper phthalocyanine, N¹,N^{1′}-([1,1′-biphenyl]-4,4′-diyl)bis(N1-phenyl-N⁴,N⁴-di-m-tolylbenzene-1,4-diamine (DNTPD), 4,4′,4″-[tris(3- methylphenyl)phenylamino] triphenylamine (m-MTDATA), 4,4′4″-Tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), polyetherketone containing triphenylamine (TPAPEK), 4-Isopropyl-4′-methyldiphenyliodonium [Tetrakis(pentafluorophenyl)borate], and dipyrazino[2,3-f: 2′,3′-h] quinoxaline-2,3,6,7,10,11- hexacarbonitrile (HATCN).

Each of the hole transport regions HTR1, HTR2, HTR3, and HTR4 may include a carbazole-based derivative such as N-phenylcarbazole and polyvinylcarbazole, a fluorine-based derivative, a triphenylamine-based derivative such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), NPB (N,N′-di(naphthalene-1-yl)-N,N′-diphenyl-benzidine), 4,4′-Cyclohexylidene bis[N,N-bis(4-methylphenyl)benzenamine] (TAPC), 4,4′-Bis[N,N′-(3-tolyl)amino]-3,3′- dimethylbiphenyl (HMTPD), and 1,3-Bis(N-carbazolyl)benzene (mCP).

In an embodiment, each of the hole transport regions HTR1, HTR2, HTR3, and HTR4 may include CzSi(9-(4-tert-Butylphenyl)-3,6-bis(triphenylsilyl)-9H-carbazole), CCP(9-phenyl-9H-3,9′-bicarbazole), or mDCP(1,3-bis(1,8-dimethyl-9H-carbazol-9-yl)benzene).

The hole transport regions HTR1, HTR2, HTR3, and HTR4 may include the compound of the above-described hole transportation region in at least one of the hole injection layers HIL1, HIL2, HIL3, and HIL4, the hole transport layer HTL1, HTL2, HTL3, and HTL4, and the hole-side additional layer.

A thickness of each of the hole transport regions HTR1, HTR2, HTR3, and HTR4 may be in a range of about 10 nm to about 1000 nm. For example, the thickness of each of the hole transport regions HTR1, HTR2, HTR3, and HTR4 may be in a range of about 10 nm to about 500 nm. A thickness of each of the hole injection layers HIL1, HIL2, HIL3, and HIL4 may be, for example, in a range of about 5 nm to about 100 nm. A thickness of each of the hole transport layers HTL1, HTL2, HTL3, and HTL4 may be in a range of about 5 nm to about 100 nm. If each of the hole transport regions HTR1, HTR2, HTR3, and HTR4 includes the hole-side additional layer, a thickness of the hole-side additional layer may be in a range of about 1 nm to about 100 nm. If the thickness of the hole transport regions HTR1, HTR2, HTR3, and HTR4 and the thickness of each of the layers included in the hole transport regions HTR1, HTR2, HTR3, and HTR4 satisfy the range as described above, a satisfactory degree of hole transport characteristics may be obtained without substantially increasing in driving voltage.

Each of the hole transport regions HTR1, HTR2, HTR3, and HTR4 may further include a charge production material in addition to the above-described material to improve the conductivity. The charge production material may be uniformly or non-uniformly dispersed into the hole transport regions HTR1, HTR2, HTR3, and HTR4. For example, the charge production material may be a p-type dopant. The p-type dopant may include at least one of a halogenated metal compound, a quinone derivative, a metal oxide derivative, and a cyano-containing compound, but the disclosure is not limited thereto. For example, the p-type dopant may include a halogenated metal compound such as CuI and RbI, a quinine derivative such as tetracyanoquinodimethane (TCNQ) and 2,3,5,6-tetrafluoro-7,7′8,8-tetracyanoquinodimethane (F4-TCNQ), and a metal oxide such as tungsten oxide and molybdenum oxide, but the disclosure is not limited thereto.

Each of the blue emission layers BEML1, BEML2, and BEML3 and the green emission layer GEML may include a host material and a dopant material. Each of the blue emission layers BEML1, BEML2, and BEML3 and the green emission layer GEML may include a material including a carbazole derivative moiety, or an amine derivative moiety as a hole transportable host material. Each of the blue emission layers BEML1, BEML2, and BEML3 and the green emission layer GEML may include a material including a nitrogen-containing aromatic ring structure such as a pyridine derivative moiety, a pyridazine derivative moiety, a pyrimidine derivative moiety, a pyrazine derivative moiety, a triazine derivative moiety, etc., as an electron transport host material.

Each of the blue emission layers BEML1, BEML2, and BEML3 and the green emission layer GEML may include an anthracene derivative, a pyrene derivative, a fluoranthene derivative, a chrysene derivative, a dihydrobenzanthracene derivative, or a triphenylene derivative as a host material. In an embodiment, each of the blue emission layer BEML1, BEML2, and BEML3 and the green emission layer GEML may further include a general host material. For example, each of the blue emission layers BEML1, BEML2, and BEML3 and the green emission layer GEML may include at least one of bis[2-(diphenylphosphino)phenyl] ether oxide (DPEPO), 4,4′-Bis(carbazol-9-yl)biphenyl (CBP), 1,3-Bis(carbazol-9-yl)benzene (mCP), 2,8-Bis(diphenylphosphoryl)dibenzo[b,d]furan (PPF), 4,4′,4″-Tris(carbazol-9-yl)-triphenylamine (TCTA), and 1,3,5-tris(1-phenyl-1H-benzo[d]imidazole-2-yl)benzene (TPBi) as a host material. However, the disclosure is not limited thereto. For example, tris(8-hydroxyquinolino) aluminum (Alq3), poly(n-vinylcarbazole) (PVK), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-Methyl-9,10-bis(naphthalen-2-yl)anthracene (MADN), hexaphenyl cyclotriphosphazene (CP1), 1,4-Bis(triphenylsilyl)benzene (UGH2), hexaphenylcyclotrisiloxane (DPSiO3), octaphenylcyclotetra siloxane (DPSiO4) may be used as a host material.

In an embodiment, each of the blue emission layers BEML1, BEML2, and BEML3 may include a styryl derivative (for example, 1,4-bis[2-(3-N-ethylcarbazoryl)vinyl]benzene (BC_{Z}VB)), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene, and a derivative thereof (for example, 1,1-dipyrene, 1,4-dipyrenylbenzene, 1,4-Bis(N,N-Diphenylamino)pyrene) as a fluorescent dopant material.

The green emission layer GEML may include a phosphorescent dopant material. For example, the green emission layer GEML may include a metal complex including iridium (IR), platinum (PT), osmium (OS), gold (AU), titanium (Ti), zirconium (ZR), harfnium (HF), europum (EU), turbium (TB) or tullium (TM). For example, bis(4,6-difluorophenylpyridinato-N,C2′)picolinate (FIrpic(iridium(III)), bis(2,4-difluorophenylpyridinato)-tetrakis(1-pyrazolyl)borate iridium(III) (Fir6), or platinum octaethyl porphyrin (PtOEP) may be used as a phosphorescent dopant material.

Each of the electron transport region ETR1, ETR2, ETR3, and ETR4 may have a layer made of a material, a layer made of different materials, or a multi-layered structure including layers made of different materials. For example, at least a portion of the electron transport regions ETR1, ETR2, ETR3, and ETR4 may include an electron transport layer ETL4 and an electron injection layer EIL4.

Each of the electron transport regions ETR1, ETR2, ETR3, and ETR4 may be formed by using various methods such as a vacuum deposition method, a spin coating method, a casting method, a Langmuir-Blodgett (LB) method, an inject printing method, a laser printing method, and a laser induced thermal imaging (LITI) method.

Each of the electron transport regions ETR1, ETR2, ETR3, and ETR4 may include an anthrasen-based compound. However, the disclosure is not limited thereto, and each of the electron transport regions ETR1, ETR2, ETR3, and ETR4 may include at least one of tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine (T2T), 2-(4-(N-phenylbenzoimidazol-1- yl)phenyl)-9,10-dinaphthylanthracene, 1,3,5-Tri(1-phenyl-1H-benzo[d]imidazol-2-yl)benzene (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4- tert-butylphenyl)-1,3,4-oxadiazole (tBu-PBD), bis(2-methyl-8-quinolinolato-N1,O8)-(1,1′-Biphenyl-4-olato)aluminum (BAlq), berylliumbis(benzoquinolin-10-olate (Bebq2), 9,10-di(naphthalene-2-yl)anthracene (ADN), 1,3-Bis[3,5-di(pyridin-3-yl)phenyl]benzene (BmPyPhB), and a mixture thereof.

In an embodiment, each of the electron transportation regions ETR1, ETR2, ETR3, and ETR4 may include a halogenated metal such as LiF, NaCl, CsF, RbCl, RbI, CuI, and KI, a lanthanide metal such as Yb, or a co-complex material of the above halogenated metal and the lanthanide metal. For example, the electron transport regions ETR1, ETR2, ETR3, and ETR4 may include KI:Yb, RbI:Yb, etc., as a co-complex material. The electron transport regions ETR1, ETR2, ETR3, and ETR4 may include at least one of Mg, Ag, Yb, and Al. For example, the electron transport regions ETR1, ETR2, ETR3, and ETR4 may include Mg and YB.

The electron transport regions ETR1, ETR2, ETR3, and ETR4 may include a metal oxide such as Li20 and BaO, or 8-hydroxyl-lithium quinolate (Liq), but the disclosure is not limited thereto. Each of electron transport regions ETR1, ETR2, ETR3, and ETR4 may also include a mixture of an electron transport material and an insulating organo metal salt. The organo metal salt may be a material having an energy band gap greater than or equal to about 4eV. For example, the organo metal salt may include a metal acetate, a metal benzoate, a metal acetoacetate, a metal acetylacetonate, or a metal stearate.

Each of the electron transport regions ETR1, ETR2, ETR3, and ETR4 may further include at least one of 2,9-dimethyl-4,7-diphenyl-1,10-phenanthroline (BCP) and 4,7-diphenyl-1,10-phenanthroline (Bphen) in addition to the above-described material, but the disclosure is not limited thereto.

In the electron transport regions ETR1, ETR2, ETR3, and ETR4, the above-described compounds in the electron transport region may be included in the electron injection layer or the electron transport layer. In case that each of the electron transportation regions ETR1, ETR2, ETR3, and ETR4 includes the electron-side additional layer, the material described above may be included in the electron-side additional layer. In an embodiment, the electron injection layer EIL4 may include at least one of Mg, Ag, Yb, and Al. The electron injection layer EIL4 may include, for example, a mixture of Mg and Yb.

A thickness of each of the electron transport regions ETR1, ETR2, ETR3, and ETR4 may be, for example, in a range of about 10 nm to about 150 nm. A thickness of the electron transport layer may be in a range of about 0.1 nm to about 100 nm. For example, the thickness of the electron transport layer may be in a range of about 0.3 nm to about 50 nm. In case that each of the electron transport layers has a thickness within the above-described range, satisfactory electron transport characteristics may be achieved without substantially increasing in driving voltage.

The second electrode EL2 may be provided on the light emitting stacks ST1, ST2, ST3, and ST4. The second electrode EL2 may be a common electrode. The second electrode EL2 may be a cathode or an anode, but the disclosure is not limited thereto. For example, in case that the first electrode EL1 is an anode, the second electrode EL2 may be a cathode, and in case that the first electrode EL1 is a cathode, the second electrode EL2 may be an anode. The second electrode EL2 may be a transflective electrode or a transmissive electrode.

In case that the second electrode EL2 is a transmissive electrode, the second electrode EL2 may be made of a metal oxide, for example, indium tin oxide (ITO), indium zinc oxide (IZO), zinc oxide (ZnO), or indium tin zinc oxide (ITZO).

In case that the second electrode EL2 is a transflective electrode or a transmissive electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture thereof (for example, AgMg, AgYb, or MgAg) In an embodiment, the second electrode EL2 may have a structure of multiple layers including a reflective layer or transflective layer and a transparent conductive layer made of indium tin oxide (ITO), indium zinc oxide (IZO), zinc oxide (ZnO), or indium tin zinc oxide (ITZO). For example, the second electrode EL2 may include the above-described metal materials, a combination of two or more metal materials of the above-described metal materials, or an oxide of the above-described metal materials.

Although not shown, the second electrode EL2 may be connected to an auxiliary electrode. In case that the second electrode EL2 is connected to an auxiliary electrode, the second electrode EL2 may be reduced in resistance.

A capping layer CPL may be further disposed on the second electrode EL2 of the light emitting element LED according to an embodiment. The capping layer CPL may include a multi-layer or a single layer.

In an embodiment, the capping layer CPL may be an organic layer or an inorganic layer. For example, the capping layer CPL may include an inorganic material such as an alkali metal compound such as LiF, an alkaline earth metal compound such as MgF₂, SiON, SiN_{X}, SiO_{y}, and the like.

For example, the capping layer CPL may include an organic material such as α-NPD, NPB, TPD, m-MTDATA, Alq3, CuPc, N4,N4,N4′,N4′-tetra (biphenyl-4-yl) biphenyl-4,4′-diamine (TPD15), 4,4′,4″-Tris (carbazol sol-9-yl) triphenylamine (TCTA), etc., and acrylate such as an epoxy resin or methacrylate.

A refractive index of the capping layer CPL may be greater than or equal to about 1.6. For example, the refractive index of the capping layer CPL may be greater than or equal to about 1.6 for light having a wavelength in a range of about 550 nm to about 660 nm.

Referring to FIG. 4A, in the light emitting element LED according to an embodiment, the electron control layer ETR may be disposed between the emission layer EML and the second electrode EL2. The electron control layer ETR may include at least one of an electron injection layer, an electron transport layer, and a hole stop layer. Referring to FIG. 4A, the electron control layer ETR may be disposed as a common layer over the emission areas EA1, EA2, and EA3 and the entire pixel defining layer PDL that divides the emission areas EA1, EA2, and EA3. However, the disclosure is not limited thereto, and the electron control layer ETR may be patterned to be separated so as to correspond to the emission areas EA1, EA2, EA3 and EA3, respectively.

The second electrode EL2 may be provided on the electron control layer ETR. The second electrode EL2 may be a common electrode. The second electrode EL2 may be a cathode or an anode, but the disclosure is not limited thereto. For example, in case that the first electrode EL1 is an anode, the second electrode EL2 may be a cathode, and in case that the first electrode EL1 is a cathode, the second electrode EL2 may be an anode. The second electrode EL2 may be a transmissive electrode, a transflective electrode, or a reflective electrode.

The encapsulation layer TFE may be disposed on the light emitting element LED. For example, in an embodiment, the encapsulation layer TFE may be disposed on the second electrode EL2. In case that the light emitting element LED includes a capping layer (not shown), the encapsulation layer TFE may be disposed on the capping layer (not shown). As described above, the encapsulation layer TFE may include at least one organic layer and at least one inorganic layer, and the inorganic layer and the organic layer may be disposed alternately.

The display panel DP according to an embodiment may include an optical structure layer OSL disposed on the display element layer DP-LED. The optical structure layer OSL may include a light control layer CCL, a color filter layer CFL, and a base layer BL.

A portion of the light control layer CCL may include a light converter. The light converter may be a quantum dot or a phosphor. The light converter may convert a wavelength of received light so that light having a converted wavelength is emitted. For example, a portion of the light control layer CCL may include quantum dots or a phosphor.

The light control layer CCL may include multiple light control patterns CCP-B, CCP-R, and CCP-G. The light control patterns CCP-B, CCP-R, and CCP-G may be spaced apart from each other. The light control patterns CCP-B, CCP-R, and CCP-G may be spaced apart from each other by the bank BMP.

The light control patterns CCP-B, CCP-R, and CCP-G may be disposed in the bank openings BOH1, BOH2, and BOH3 defined in the bank BMP. However, the disclosure is not limited thereto. Referring to FIG. 4A, the bank BMP may have a polygonal shape in a cross-section and non-overlap the light control patterns CCP-B, CCP-R, and CCP-G in a plan view, but an edge of a portion of the light control patterns CCP-B, CCP-R, and CCP-G may at least partially overlap the bank BMP in a plan view. For example, an edge of the second light control pattern CCP-R may overlap the bank BMP in a plan view.

The bank BMP may include a base resin and an additive. The base resin may generally be made of a resin composition that may be referred to as a binder. The additive may include a coupling agent and/or a photoinitiator. The additive may further include a dispersing agent.

In an embodiment, the bank BMP included in the light control layer CCL may be optically transparent. The bank BMP may contain an optically transparent material. The base resin included in the bank BMP may be optically transparent. The bank BMP may include a material having transmittance greater than or equal to about 85% in a visible light range. The bank BMP may not include a separate coloring agent. The bank BMP may include a black dye and a black pigment, which are mixed with the base resin. In an embodiment, the bank BMP may not include a light blocking material having a black color such as carbon black or a pigment or dye having a blue color.

A portion of the bank BMP may overlap at least a portion of the light control patterns CCP-B, CCP-R, and CCP-G in a plan view. As illustrated in FIG. 4A, a portion of the bank BMP may overlap the first light control pattern CCP-B in a plan view. A portion of the bank BMP may overlap the third light control pattern CCP-G in a plan view. A portion of the bank BMP may be disposed on the first light control pattern CCP-B and the third light control pattern CCP-G. In the light control layer CCL according to an embodiment, the bank BMP may include a transparent material and overlap the first light control pattern CCP-B and the third light control pattern CCP-G, which are formed through a photoresist process, in a plan view.

In the display panel DP according to an embodiment, a stepped portion may be formed at a portion between the top surface of the bank BMP and the top surfaces of the light control patterns CCP-B, CCP-R, and CCP-G. For example, the top surface of the bank BMP may be higher than the top surface of at least a portion of the light control patterns CCP-B, CCP-R, and CCP-G. A height difference between the top surface of the bank BMP and the top surface of each of the light control patterns CCP-B, CCP-R, and CCP-G may be, for example, in a range of about 2 μm to about 3 μm.

The light control pattern CCP-B, CCP-R, and CCP-G may be a portion that converts a wavelength of light provided from the display element layer DP-LED or transmits the received light.

The light control layer CCL may include a first light control pattern CCP-B that provides blue light as first light, a second light control pattern CCP-R that provides red light as second light, and a third light control pattern CCP-G that provides green light as third light. The light control layer CCL may include a first light control pattern CCP-B that transmits the source light provided from the light emitting element LED, for example, the first light, a second light control pattern CCP-R that converts the source light into the second light, and a third light control pattern CCP-G that transmits the third light.

A portion of the light control patterns CCP-B, CCP-R, and CCP-G may be formed by an inkjet process. In an embodiment, the second light control pattern CCP-R may be formed by the inkjet process. A liquid ink composition may be provided inside the second bank opening BOH2, and the provided ink composition may be polymerized through a thermal curing process or a photo curing process to form the second light control pattern CCP-R.

The rest of the light control patterns CCP-B, CCP-R, and CCP-G may be formed by a photoresist process. In an embodiment, the first light control pattern CCP-B and the third light control pattern CCP-G may be formed through the photoresist process. After a photoresist composition is provided inside at least each of the first bank opening BOH1 and the third bank opening BOH3, the provided photoresist composition may be cured to form the first light control pattern CCP-B and the third light control pattern CCP-G.

A portion of the light control patterns CCP-B, CCP-R, and CCP-G may include quantum dots that convert the source light into light having a specific wavelength. As described above, the second light control pattern CCP-R may include a first quantum dot QD1 that converts the source light into light having a second wavelength.

Each of the light control patterns CCP-B, CCP-R, and CCP-G may further include a scatterer SP. The second light control pattern CCP-R may include a first quantum dot QD1 and a scatterer SP, and each of the first light control pattern CCP-B and the third light control pattern CCP-G may not include the quantum dots, but include the scatterer SP. Each of the first light control pattern CCP-B, the second light control pattern CCP-R, and the third light control pattern CCP-G may further include base resins BR1, BR2, and BR3 that disperse the quantum dots QD1 and the scatterer SP. Each of the first light control pattern CCP-B and the third light control pattern CCP-G may be formed through the photoresist process as described below and thus may include a photosensitive resin.

The light control layer CCL may include a metal pattern MSP. A portion of the metal pattern MSP may overlap the bank BMP in a plan view. The metal pattern MSP may be disposed between at least the first light control pattern CCP-B and the second light control pattern CCP-R. The metal pattern MSP may be disposed between the second light control pattern CCP-R and the third light control pattern CCP-G. A portion of the metal pattern MSP may overlap at least a portion of the first light control pattern CCP-B and the second light control pattern CCP-R in a plan view. The metal pattern MSP may be disposed between the adjacent light control patterns CCP-B, CCP-R, and CCP-G along the first direction DR1 to prevent colors from being mixed between the adjacent light control patterns CCP-B, CCP-R, and CCP-G.

The metal pattern MSP may include a reflective metal. The metal pattern MSP may include a highly reflective metal. The metal pattern MSP may include, for example, Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture thereof (for example, a mixture of Ag and Mg), which have high reflectivity.

The light control layer CCL may include a first barrier layer CAP1 disposed on a surface of each of the light control patterns CCP-B, CCP-R, and CCP-G. The light control layer CCL may include a first barrier layer CAP1 spaced apart from the display element layer DP-LED with the light control patterns CCP-B, CCP-R, and CCP-G between the first barrier layer CAP1 and the display element layer DP-LED and a second battery layer CAP2 adjacent to the display element layer DP-LED.

The first barrier layer CAP1 may be disposed to follow the stepped portion between the bank BMP and the light control patterns CCP-B, CCP-R, and CCP-G. The first barrier layer CAP1 may be disposed below (e.g., directly below) the filling layer FML.

In the display panel DP, the optical structure layer OSL may include a color filter layer CFL disposed on the light control layer CCL. The color filter layer CFL may include color filters CF1, CF2, and CF3. The color filter layer CFL may include a first color filter CF1 that transmits the first light, a second color filter CF2 that transmits the second light, and a third color filter CF3 that transmits the source light. In an embodiment, the first color filter CF1 may be a red filter, the second color filter CF2 may be a green filter, and the third color filter CF3 may be a blue filter.

Each of the color filters CF1, CF2, and CF3 may include a polymer photosensitive resin and a colorant. The first color filter CF1 may include a blue colorant, the second color filter CF2 may include a red colorant, and the third color filter CF3 may include a green colorant. The first color filter CF1 may include a blue pigment or blue dye, the second color filter CF2 may include a red pigment or red dye, and the third color filter CF3 may include a green pigment or green dye.

The first to third color filters CF1, CF2, and CF3 may be disposed to correspond to the first pixel area PXA-B, the second pixel area PXA-R, and the third pixel area PXA-G, respectively. For example, each of the first to third color filters CF1, CF2, and CF3 may be disposed to correspond to the first to third light control patterns CCP-B, CCP-R, and CCP-G, respectively.

In an embodiment, the color filters CF1, CF2, and CF3 that transmit different light may overlap each other in a plan view so as to correspond to the peripheral area NPXA disposed between the pixel areas PXA-B, PXA-R, and PXA-G. The color filters CF1, CF2, and CF3 may overlap each other in the third direction DR3, which is the thickness direction, to set boundaries between the adjacent emission areas PXA-B, PXA-R, and PXA-G. Unlike that is illustrated in the drawings, the color filter layer CFL may include a light blocking part (not shown) to set boundaries between the adjacent color filters CF1, CF2, and CF3. The light blocking part (not shown) may be provided as a blue filter or may include an organic light blocking material containing a black pigment or black dye or an inorganic light blocking material.

The optical structure layer OSL may include a filling layer FML disposed between the light control layer CCL and the color filter layer CFL. The filling layer FML may be disposed between the light control patterns CCP-B, CCP-R, and CCP-G and the color filters CF1, CF2, and CF3. The filling layer FML may be disposed on the light control layer CCL to prevent the light control patterns CCP-B, CCP-R, and CCP-G from being exposed to moisture/oxygen. In an embodiment, the filling layer FML may be disposed between the light control patterns CCP-B, CCP-R, and CCP-G and the color filters CF1, CF2, and CF3 to improve light extraction efficiency or prevent reflected light from being incident again into the light control layer CCL, thereby serving as an optical functional layer. The filling layer FML may be a layer having a lower refractive index compared to other adjacent layers.

In an embodiment, the optical structure layer OSL may further include a base layer BL disposed on the color filter layer CFL. The base layer BL may be a member that provides a base surface on which the color filter layer CFL and the light control layer CCL are disposed. The base layer BL may include a glass substrate, a metal substrate, a plastic substrate, and the like. However, the disclosure is not limited thereto. For example, the base layer BL may be an inorganic layer, an organic layer, or a composite layer. In another embodiment, the base layer BL may be omitted in an embodiment, unlike that is illustrated above.

FIGS. 4B to 4D schematically illustrate display panels DP-1, DP-2, and DP-3 according to another embodiments of the display panel DP, which is different from FIG. 4A.

Referring to FIG. 4B, the display panel DP-1 according to an embodiment may include a lower panel including a base substrate BS, a circuit element layer DP-CL disposed on the base substrate BS, and a display element layer DP-LED disposed on the circuit element layer DP-CL, and an optical structure layer OSL-1. The optical structure layer OSL-1 may include a light control layer CCL-1, a color filter layer CFL-1, and a base layer BL.

The display panel DP-1 according to an embodiment may include a lower panel including the display element layer DP-LED and an upper panel (optical structure layer OSL-1) including a light control layer CCL and a color filter layer CFL, and in an embodiment, a filling layer FML-1 may be disposed between the lower panel and the upper panel OSL-1.

In an embodiment, the filling layer FML-1 may be filled between the display element layer DP-LED and the light control layer CCL-1. The filling layer FML-1 may be disposed on (e.g., directly on) an encapsulation layer TFE, and the second barrier layer CAP2 may be disposed on (e.g., directly on) the filling layer FML-1. A bottom surface of the filling layer FML-1 may be in contact with a top surface of the encapsulation layer TFE, and the top surface of the filling layer FML-1 may be in contact with a bottom surface of the first barrier layer CAP1.

The filling layer FML-1 may function as a buffer between the display element layer DP-LED and the light control layer CCL-1. In an embodiment, the filling layer FML-1 may perform an impact absorption function and increase a strength of the display panel DP-1. The filling layer FML-1 may be made of a filling resin containing a polymer resin. For example, the filling layer FML-1 may be made of a filling layer resin including an acrylic resin, an epoxy resin, or the like.

Compared to the display panel DP illustrated in FIG. 4A, in the display panel DP-1 according to an embodiment, which is illustrated in FIG. 4B, the filling layer FML-1 may be disposed between the display element layer DP-LED and light control layer CCL-1. For example, in the display panel DP-1 of FIG. 4B, the circuit element layer DP-CL and the display element layer DP-LED may be sequentially disposed in the lower panel by using a surface of the base substrate BS as a base surface, and the color filter layer CFL and the light control layer CCL-1 may be sequentially disposed in the upper panel (optical structure layer OSL-1) by using a surface of the base layer BL as a base surface, and the lower panel and the upper panel may be bonded to each other with the filling layer FML-1.

In the display panel DP-1 according to an embodiment, a stepped portion may occur at a portion between the bottom surface of the bank BMP and the bottom surfaces of the light control patterns CCP-B, CCP-R, and CCP-G. For example, the bottom surface of the bank BMP may be defined below the bottom surfaces of the light control patterns CCP-B, CCP-R, and CCP-G. A height difference between the bottom surface of the bank BMP and the bottom surface of each of the light control patterns CCP-B, CCP-R, and CCP-G may be, for example, in a range of about 2 μm to about 3 μm.

The first barrier layer CAP1 may be disposed to follow the stepped portion between the bank BMP and the light control patterns CCP-B, CCP-R, and CCP-G. The first barrier layer CAP1 may be disposed on (e.g., directly on) the filling layer FML-1.

The display panel DP-1 according to an embodiment may include a low refractive layer LR. The low refractive layer LR may be disposed between the light control layer CCL-1 and the color filter layer CFL. The low refractive layer LR may be disposed on the light control layer CCL-1 to prevent the light control patterns CCP-B, CCP-R, and CCP-G from being exposed to moisture/oxygen. In an embodiment, the low refractive layer LR may be disposed between the light control patterns CCP-B, CCP-R, and CCP-G and the color filters CF1, CF2, and CF3 to improve light extraction efficiency or prevent reflected light from being incident again into the light control layer CCL-1, thereby serving as an optical functional layer. The low refractive layer LR may be a layer having a lower refractive index compared to the adjacent layers.

The low refractive layer LR may include at least one inorganic layer. For example, the low refractive layer LR may include at least one of silicon nitride, aluminum nitride, zirconium nitride, titanium nitride, hafnium nitride, titanium nitride, silicon oxide, aluminum oxide, titanium oxide, tin oxide, cesium oxide, silicon oxynitride, and a metal thin film having secured light transmittance. However, the disclosure is not limited thereto, and the low refractive layer LR may include an organic layer. For example, the low refractive layer LR may have a structure in which multiple hollow particles are dispersed in an organic polymer resin. The low refractive layer LR may be provided as a single layer or multiple layers.

Referring to FIG. 4C, the display panel DP-2 according to an embodiment may include a lower panel including a base substrate BS, a circuit element layer DP-CL disposed on the base substrate BS, and a display element layer DP-LED disposed on the circuit element layer DP-CL, and an optical structure layer OSL-2. In the display panel DP-2 according to an embodiment, the optical structure layer OSL-2 may include a light control layer CCL, a low refractive layer LR-1, a color filter layer CFL-1, and a base layer BL-1, which are sequentially laminated on a thin film encapsulation layer TFE. The optical structure layer OSL-2 may include a first barrier layer CAP1 and a second barrier layer CAP2, which are disposed on top and bottom surfaces of the light control layer CCL.

The light control layer CCL may be disposed on the display element layer DP-LED and the thin film encapsulation layer TFE with the second barrier layer CAP2 between the light control layer CCL and the thin film encapsulation layer TFE. The light control layer CCL may include multiple banks BMP and light control patterns CCP-B, CCP-R, and CCP-G disposed between the banks BMP. A low refractive layer LR-1 may be disposed on the light control layer CCL.

The color filter layer CFL-1 may include multiple color filters CF1, CF2, and CF3 and a light blocking part BM.

Compared to the display panel DP-1 illustrated in FIG. 4B, in a display panel DP-2 according to an embodiment, which is illustrated in FIG. 4C, a light control layer CCL, a low refractive layer LR-1, and a color filter layer CFL-1 may be disposed using a top surface of a thin film encapsulation layer TFE as a base surface. For example, the light control patterns CCP-B, CCP-R, and CCP-G of the light control layer CCL may be formed on the thin film encapsulation layer TFE through a continuous process, and the color filters CF1, CF2, and CF3 of the color filter layer CFL-1 may be sequentially formed on the light control layer CCL through a continuous process. The color filter layer CFL-1 may be formed using a top surface of the low refractive layer LR-1 as the base surface and may have a shape different from that illustrated in FIGS. 4A and 4B.

In the color filter layer CFL-1 according to an embodiment, the light blocking part BM may be a black matrix. The light blocking part BM may include an organic light blocking material or an inorganic light blocking material including a black pigment or black dye. The light blocking part BM may prevent light leakage and set boundaries between the adjacent color filters CF1, CF2, and CF3.

Referring to FIG. 4D, the display element layer DP-LED1 included in the display panel DP-3 according to an embodiment may include a light emitting element LED-1, and the light emitting element LED-1 may be a micro LED or a nano LED. The light emitting element LED-1 may be disposed between the pixel defining layers PDL and may be electrically connected to a contact part S-C, and a length and width of the light emitting element LED-1 may be in a range of hundreds of nanometers to hundreds of micrometers. The light emitting element LED-1 may be an LED including an active layer and at least one semiconductor material layer. The light emitting element LED-1 may further include an insulating layer covering surfaces of the active layer and the semiconductor material layer. The light emitting element LED-1 may be patterned to overlap each of the emission areas PXA-B, PXA-R, and PXA-G in a plan view. The display panel DP may include a buffer layer BFL disposed on the light emitting element LED-1. The buffer layer BFL may be disposed on the light-emitting element LED-1 to cover the light-emitting element LED-1. In another embodiment, the buffer layer BFL may be omitted.

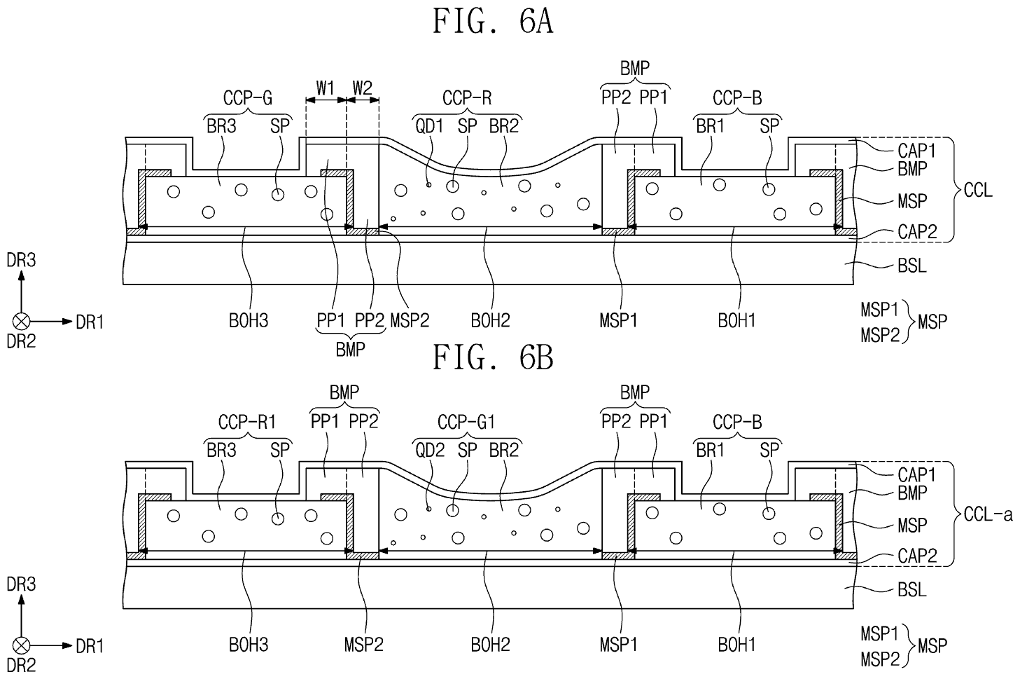

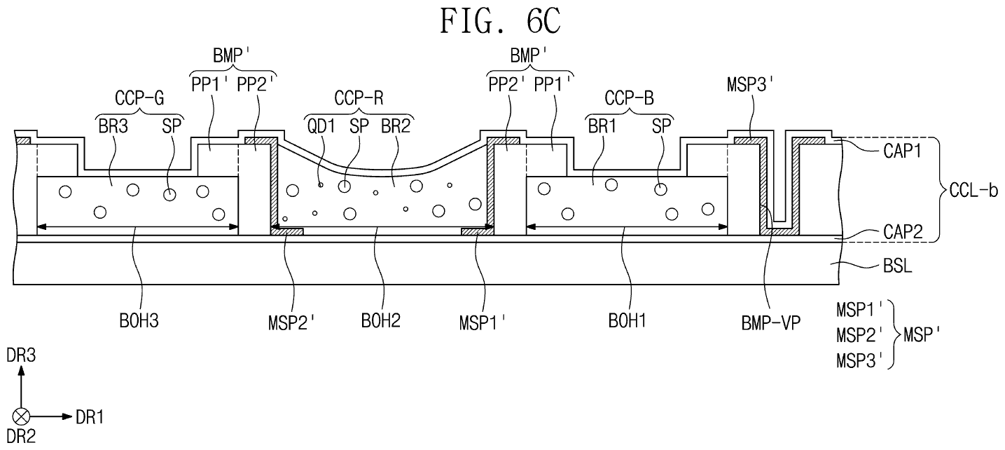

FIGS. 6A to 6C are enlarged schematic cross-sectional views illustrating a portion of partial components of the display panel according to an embodiment of the disclosure. FIGS. 6A to 6C schematically illustrate a cross-section corresponding to FIG. 4A by focusing on components included in the light control layer CCL (see FIG. 4A) of the display panel according to an embodiment.

Referring to FIGS. 2, 3, 4A, and 6A together, the light control layer CCL may include multiple light control patterns CCP-B, CCP-R, and CCP-G, a bank BMP, and a metal pattern MSP. The light control layer CCL may further include a first barrier layer CAP1 and a second barrier layer CAP2.

The light control layer CCL may be disposed on the base member BSL. The base member BSL may be a member that provides a base surface on which the light control layer CCL is disposed. The base member BSL may be the encapsulation layer TFE described above in FIG. 4A or the low refractive layer LR described above in FIG. 4B.

The light control patterns CCP-B, CCP-R, and CCP-G included in the light control layer CCL may be spaced apart from each other. The light control patterns CCP-B, CCP-R, and CCP-G may be spaced apart from each other by the bank BMP.

The bank BMP may include a base resin and an additive. The base resin may generally be made of a resin composition that may be referred to as a binder. The additive may include a coupling agent and/or a photoinitiator. The additive may further include a dispersing agent.

In an embodiment, the bank BMP included in the light control layer CCL may be optically transparent. The bank BMP may include an optically transparent material. The base resin included in the bank BMP may be optically transparent. The bank BMP may include a material having transmittance greater than or equal to about 85% in a visible light range. The bank BMP may not include a separate coloring agent. The bank BMP may include a black dye and a black pigment, which are mixed with the base resin. In an embodiment, the bank BMP may not include a light blocking material having a black color such as carbon black or a pigment or dye having a blue color.

A bank opening BOH may be defined in the bank BMP. The light control patterns CCP-B, CCP-R, and CCP-G may be disposed in the bank openings BOH1, BOH2, and BOH3 defined in the bank BMP.

A portion of the bank BMP may overlap at least a portion of the light control patterns CCP-B, CCP-R, and CCP-G in a plan view. As illustrated in FIG. 6A, a portion of the bank BMP may overlap the first light control pattern CCP-B in a plan view. A portion of the bank BMP may be disposed on the first light control pattern CCP-B. The bank BMP may include a first portion PP1 disposed on a side of the first light control pattern CCP-B, and a second portion PP2 that does not overlap the first light control pattern CCP-B in a plan view. The first portion PP1 and the second portion PP2 may have an integrated shape. The first portion PP1 and the second portion PP2 may include a same material and may be formed through a same process. A portion of the bank BMP may overlap the third light control pattern CCP-G in a plan view. A portion of the bank BMP may be disposed on the third light control pattern CCP-G. The bank BMP may include a first portion PP1 disposed on a side of the third light control pattern CCP-G, and a second portion PP2 that does not overlap the third light control pattern CCP-G in a plan view.

In the first direction DR1, the first portion PP1 may have a first width W1, and the second portion PP2 may have a second width W2. The first width W1 may be greater than the second width W2. In an embodiment, the first width W1 may be in a range of about 6 μm to about 9 μm. The second width W2 may be in a range of about 1.5 μm to about 4.5 μm. The first width W1 may be greater than twice the second width W2. In the light control layer CCL according to an embodiment, the first width W1 may be designed to be greater than the second width W2, thereby securing a wide area on which the metal pattern MSP is disposed while increasing in aperture ratio of the bank BMP and thus improving display efficiency of the display panel including the light control layer CCL.

In the light control layer CCL according to an embodiment, the bank BMP may include a transparent material and overlap the first light control pattern CCP-B and the third light control pattern CCP-G, which are formed through a photoresist process, in a plan view.

A portion of the light control patterns CCP-B, CCP-R, and CCP-G may be formed by an inkjet process. In an embodiment, the second light control pattern CCP-R may be formed by an inkjet process. A liquid ink composition may be provided inside the second bank opening BOH2, and the provided ink composition may be polymerized through a thermal curing process or a photo curing process to form the second light control pattern CCP-R.

The rest of the light control patterns CCP-B, CCP-R, and CCP-G may be formed by a photoresist process. In an embodiment, the first light control pattern CCP-B and the third light control pattern CCP-G may be formed through a photoresist process. After a photoresist composition is provided inside at least each of the first bank opening BOH1 and the third bank opening BOH3, the provided photoresist composition may be cured to form the first light control pattern CCP-B and the third light control pattern CCP-G.

In the display panel DP according to an embodiment, a stepped portion may be formed at a portion between the top surface of the bank BMP and the top surfaces of the light control patterns CCP-B, CCP-R, and CCP-G. For example, the top surface of the bank BMP may be higher than the top surface of at least a portion of the light control patterns CCP-B, CCP-R, and CCP-G. The bank BMP may have a thicker thickness than the first light control pattern CCP-B and the third light control pattern CCP-G, so the top surface of the bank BMP may be higher than the top surface of the first light control pattern CCP-B and the top surface of the third light control pattern CCP-G. The top surface of each of the first portion PP1 and the second portion PP2 of the bank BMP may be higher than the top surface of each of the first light control pattern CCP-B and the third light control pattern CCP-G.

The second light control pattern CCP-R may have a thickness greater than the thickness of each of the first light control pattern CCP-B and the third light control pattern CCP-G and may have a thickness less than or equal to the thickness of the bank BMP. As illustrated in FIG. 6A, the top surface of the second light control pattern CCP-R may be higher than the top surface of each of the first light control pattern CCP-B and the third light control pattern CCP-G. The second light control pattern CCP-R may have a shape of which a thickness decreases from a portion adjacent to the bank BMP to a central portion. The top surface of the second light control pattern CCP-R and the top surface of the bank BMP may have a same height, or the top surface of the second light control pattern CCP-R may be lower than the top surface of the bank BMP.

As described above, the second light control pattern CCP-R may include a first quantum dot QD1 that converts the source light into light having a second wavelength. Each of the light control patterns CCP-B, CCP-R, and CCP-G may further include a scatterer SP. The second light control pattern CCP-R may include a first quantum dot QD1 and a scatterer SP. Each of the first light control pattern CCP-B and the third light control pattern CCP-G may not include a light emitter such as the quantum dot, but may include a scatterer SP. Each of the first light control pattern CCP-B, the second light control pattern CCP-R, and the third light control pattern CCP-G may further include base resins BR1, BR2, and BR3 that disperse the quantum dots QD1 and the scatterer SP. Each of the first light control pattern CCP-B and the third light control pattern CCP-G may be formed through a photoresist process and thus may include a photosensitive resin. The first base resin BR1 and the third base resin BR3, which are included in each of the first light control pattern CCP-B and the third light control pattern CCP-G, may be a photosensitive resin. The second base resin BR2 included in the second light control pattern CCP-R may be an inkjet resin. The first base resin BR1 and the third base resin BR3 may include a same material. In the light control layer CCL according to an embodiment, the second light control pattern CCP-R corresponding to a red pixel area may include a first quantum dot QD1 and be formed through an inkjet process, and each of the first light control pattern CCP-B and the third light control pattern CCP-G, which correspond to a blue pixel area and a green pixel area, respectively, may not include a quantum dot and be formed through a photoresist process.

The light control layer CCL may include a metal pattern MSP. A portion of the metal pattern MSP may overlap the bank BMP in a plan view. The metal pattern MSP may include a first metal pattern MSP1 disposed between the first light control pattern CCP-B and the second light control pattern CCP-R and a second metal pattern MSP2 disposed between the second light control pattern CCP-R and the third light control patterns CCP-G.

A portion of the metal pattern MSP may overlap at least a portion of the first light control pattern CCP-B and the second light control pattern CCP-R in a plan view. As illustrated in FIG. 6A, a portion of the metal pattern MSP may overlap the first light control pattern CCP-B in a plan view. A portion of the metal pattern MSP may be disposed on the first light control pattern CCP-B. A portion of the first metal pattern MSP1 may be disposed on the first light control pattern CCP-B.

The first metal pattern MSP1 may be disposed between the first light control pattern CCP-B and the bank BMP. The first metal pattern MSP1 may be disposed adjacent to at least a side surface of the first light control pattern CCP-B and may be disposed between the second portion PP2 and the first light control pattern CCP-B in the first direction DR1. At least a portion of the first metal pattern MSP1 may be in contact with the first light control pattern CCP-B. A portion of the first metal pattern MSP1 may be in contact with the side surface of the first light control pattern CCP-B, and a portion of the first metal pattern MSP1 may be in contact with a portion of the top surface of the first light control pattern CCP-B.

A portion of the metal pattern MSP may overlap the third light control pattern CCP-G in a plan view. A portion of the metal pattern MSP may be disposed on the third light control pattern CCP-G. A portion of the second metal pattern MSP2 may be disposed on the third light control pattern CCP-G.

The second metal pattern MSP2 may be disposed between the third light control pattern CCP-G and the bank BMP. The second metal pattern MSP2 may be disposed adjacent to at least a side surface of the third light control pattern CCP-G and may be disposed between the third light control pattern CCP-G and the second portion PP2 in the first direction DR1. At least a portion of the second metal pattern MSP2 may be in contact with the third light control pattern CCP-G. A portion of the second metal pattern MSP2 may be in contact with the side surface of the third light control pattern CCP-G, and a portion of the second metal pattern MSP2 may be in contact with a portion of the top surface of the third light control pattern CCP-G.

The metal pattern MSP may be provided as a single layer between the first light control pattern CCP-B and the second light control pattern CCP-R. A first metal pattern MSP1 provided as a single layer may be disposed between the first light control pattern CCP-B and the second light control pattern CCP-R. Based on the first direction DR1, the first metal pattern MSP1 may be in contact with the side surface of the first light control pattern CCP-B, the second portion PP2 of the bank BMP may be in contact with the side surface of the first metal pattern MSP1, and the second light control pattern CCP-R may be in contact with the side surface of the second portion PP2. The metal pattern MSP may be provided as a single layer between the second light control pattern CCP-R and the third light control pattern CCP-G. A second metal pattern MSP2 provided as a single layer may be disposed between the second light control pattern CCP-R and the third light control pattern CCP-G. Based on the first direction DR1, the second metal pattern MSP2 may be in contact with the side surface of the third light control pattern CCP-G, the second portion PP2 of the bank BMP may be in contact with the second metal pattern MSP2, and the second light control pattern CCP-R may be in contact with the side surface of the second portion PP2.

The metal pattern MSP may include a reflective metal. The metal pattern MSP may include a highly reflective metal. The metal pattern MSP may include, for example, Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture thereof (for example, a mixture of Ag and Mg), which have high reflectivity.

The light control layer CCL may further include a first barrier layer CAP1 disposed on a surface of each of the light control patterns CCP-B, CCP-R, and CCP-G, and a second barrier layer CAP2 disposed on another surface of each of the light control patterns CCP-B, CCP-R, and CCP-G. The first barrier layer CAP1 may be disposed to follow the stepped portion between the bank BMP and the light control patterns CCP-B, CCP-R, and CCP-G.

The light control layer CCL included in the display panel according to an embodiment may include an optically transparent bank BMP, and a portion of the bank BMP may overlap the first light control pattern CCP-B in a plan view. In an embodiment, the light control layer CCL according to an embodiment may include a metal pattern MSP that overlaps at least a portion of the first light control pattern CCP-B and the second light control pattern CCP-R in a plan view. In the display panel according to an embodiment, the metal pattern MSP may improve light conversion efficiency of the light control patterns CCP-B, CCP-R, and CCP-G. In an embodiment, the optically transparent bank BMP may be disposed on a portion of an upper portion of the first light control pattern CCP-B to secure a wide area on which the metal pattern MSP is disposed while increasing in aperture ratio of the bank BMP. Thus, the display panel including the light control layer CCL may have high resolution and improved display efficiency.

Referring to FIG. 6B, unlike the embodiment illustrated in FIGS. 4A and 6A, the second light control pattern CCP-G1 may include a second quantum dot QD2. In the second light control pattern CCP-G1, the second quantum dot QD2 may convert source light into green light. The second quantum dot QD2 may have a green emission color. The second pixel area corresponding to the second bank opening BOH2 in which the second light control pattern CCP-G1 is disposed may emit light having an emission wavelength in a range of about 520 nm to about 600 nm.

In the light control layer CCL-a according to an embodiment illustrated in FIG. 6B, the second light control pattern CCP-G1 may include a second quantum dot QD2 and a scatterer SP, and each of the first light control pattern CCP-B and the first light control pattern CCP-G1 may not include a quantum dot, but include the scatterer SP. Each of the first light control pattern CCP-B and the third light control pattern CCP-R1 may not include a light emitter such as a quantum dot, but may include the scatterer SP. Each of the first light control pattern CCP-B, the second light control pattern CCP-G1, and the third light control pattern CCP-R1 may further include base resins BR1, BR2, and BR3 that disperse the quantum dots QD2 and the scatterer SP. Each of the first light control pattern CCP-B and the third light control pattern CCP-R1 may be formed through a photoresist process and thus may include a photosensitive resin. The first base resin BR1 and the third base resin BR3, which are included in each of the first light control pattern CCP-B and the third light control pattern CCP-R1, may be a photosensitive resin. The second base resin BR2 included in the second light control pattern CCP-G1 may be an inkjet resin. In the light control layer CCL-a according to an embodiment, the second light control pattern CCP-G1 corresponding to a green pixel area may include a second quantum dot QD2 and be formed through an inkjet process, and each of the first light control pattern CCP-B and the third light control pattern CCP-R1, which correspond to a blue pixel area and a red pixel area, respectively, may not include a quantum dot and be formed through a photoresist process.

The light control patterns CCP-B, CCP-G1, and CCP-R1 included in the light control layer CCL-a may be spaced apart from each other. The light control patterns CCP-B, CCP-G1, and CCP-R1 may be spaced apart from each other by the bank BMP.

A bank opening BOH may be defined in the bank BMP. The light control patterns CCP-B, CCP-G1, and CCP-R1 may be disposed in the bank openings BOH1, BOH2, and BOH3 defined in the bank BMP.

A portion of the bank BMP may overlap at least a portion of the light control patterns CCP-B, CCP-G1, and CCP-R1 in a plan view. As illustrated in FIG. 6B, a portion of the bank BMP may overlap the first light control pattern CCP-B in a plan view. A portion of the bank BMP may be disposed on the first light control pattern CCP-B. The bank BMP may include a first portion PP1 disposed on a side of the first light control pattern CCP-B, and a second portion PP2 that does not overlap the first light control pattern CCP-B in a plan view.

A portion of the bank BMP may overlap the third light control pattern CCP-R1 in a plan view. A portion of the bank BMP may be disposed on the third light control pattern CCP-R1. The bank BMP may include a first portion PP1 disposed on a side of the third light control pattern CCP-R1, and a second portion PP2 that does not overlap the third light control pattern CCP-R1 in a plan view.

In the light control layer CCL-a according to an embodiment, the bank BMP may include a transparent material and overlap the first light control pattern CCP-B and the third light control pattern CCP-R1, which are formed through a photoresist process, in a plan view.

A portion of the light control patterns CCP-B, CCP-G1, and CCP-R1 may be formed by an inkjet process. In an embodiment, the second light control pattern CCP-G1 may be formed by an inkjet process. A liquid ink composition may be provided inside the second bank opening BOH2, and the ink composition may be polymerized through a thermal curing process or a photo curing process to form the second light control pattern CCP-G1.

The rest of the light control patterns CCP-B, CCP-G1, and CCP-R1 may be formed by a photoresist process. In an embodiment, the first light control pattern CCP-B and the third light control pattern CCP-R1 may be formed through a photoresist process. After a photoresist composition is provided inside at least each of the first bank opening BOH1 and the third bank opening BOH3, the photoresist composition may be cured to form the first light control pattern CCP-B and the third light control pattern CCP-R1.

In the display panel DP according to an embodiment, a stepped portion may be formed at a portion between the top surface of the bank BMP and the top surfaces of the light control patterns CCP-B, CCP-G1, and CCP-R1. For example, the top surface of the bank BMP may be higher than the top surface of at least a portion of the light control patterns CCP-B, CCP-G1, and CCP-R1. The bank BMP may have a thicker thickness than the first light control pattern CCP-B and the third light control pattern CCP-R1, so the top surface of the bank BMP may be higher than the top surface of the first light control pattern CCP-B and the top surface of the third light control pattern CCP-R1. The top surface of each of the first portion PP1 and the second portion PP2 of the bank BMP may be higher than the top surface of each of the first light control pattern CCP-B and the third light control pattern CCP-R1.

The second light control pattern CCP-G1 may have a thickness greater than the thickness of each of the first light control pattern CCP-B and the third light control pattern CCP-R1 and may have a thickness less than or equal to the thickness of the bank BMP. As illustrated in FIG. 6B, the top surface of the second light control pattern CCP-G1 may be higher than the top surface of each of the first light control pattern CCP-B and the third light control pattern CCP-R1. The second light control pattern CCP-G1 may have a shape of which a thickness decreases from a portion adjacent to the bank BMP to a central portion. The top surface of the second light control pattern CCP-G1 and the top surface of the bank BMP may have a same height, or the top surface of the second light control pattern CCP-G1 may be lower than the top surface of the bank BMP.

The light control layer CCL-a may include a metal pattern MSP. A portion of the metal pattern MSP may overlap the bank BMP in a plan view. The metal pattern MSP may include a first metal pattern MSP1 disposed between the first light control pattern CCP-B and the second light control pattern CCP-G1 and a second metal pattern MSP2 disposed between the second light control pattern CCP-G1 and the third light control patterns CCP-R1.

A portion of the metal pattern MSP may overlap at least a portion of the first light control pattern CCP-B and the third light control pattern CCP-RI in a plan view. As illustrated in FIG. 6B, a portion of the metal pattern MSP may overlap the first light control pattern CCP-B in a plan view. A portion of the metal pattern MSP may be disposed on the first light control pattern CCP-B. A portion of the first metal pattern MSP1 may be disposed on the first light control pattern CCP-B.

The first metal pattern MSP1 may be disposed between the first light control pattern CCP-B and the bank BMP. The first metal pattern MSP1 may be disposed adjacent to at least a side surface of the first light control pattern CCP-B and may be disposed between the second portion PP2 and the first light control pattern CCP-B in the first direction DR1. At least a portion of the first metal pattern MSP1 may be in contact with the first light control pattern CCP-B. A portion of the first metal pattern MSP1 may be in contact with the side surface of the first light control pattern CCP-B, and a portion of the first metal pattern MSP1 may be in contact with a portion of the top surface of the first light control pattern CCP-B.

A portion of the metal pattern MSP may overlap the third light control pattern CCP-R1 in a plan view. A portion of the metal pattern MSP may be disposed on the third light control pattern CCP-R1. A portion of the second metal pattern MSP2 may be disposed on the third light control pattern CCP-R1.

The second metal pattern MSP2 may be disposed between the third light control pattern CCP-R1 and the bank BMP. The second metal pattern MSP2 may be disposed adjacent to at least a side surface of the third light control pattern CCP-R1 and may be disposed between the third light control pattern CCP-R1 and the second portion PP2 in the first direction DR1. At least a portion of the second metal pattern MSP2 may be in contact with the third light control pattern CCP-R1. A portion of the second metal pattern MSP2 may be in contact with the side surface of the third light control pattern CCP-R1, and a portion of the second metal pattern MSP2 may be in contact with a portion of the top surface of the third light control pattern CCP-R1.

The metal pattern MSP may be provided as a single layer between the first light control pattern CCP-B and the second light control pattern CCP-G1. A first metal pattern MSP1 provided as a single layer may be disposed between the first light control pattern CCP-B and the second light control pattern CCP-G1. Based on the first direction DR1, the first metal pattern MSP1 may be in contact with the side surface of the first light control pattern CCP-B, the second portion PP2 of the bank BMP may be in contact with the side surface of the first metal pattern MSP1, and the second light control pattern CCP-G1 may be in contact with the side surface of the second portion PP2. The metal pattern MSP may be provided as a single layer between the second light control pattern CCP-G1 and the third light control pattern CCP-R1. A second metal pattern MSP2 provided as a single layer may be disposed between the second light control pattern CCP-G1 and the third light control pattern CCP-R1. Based on a direction opposite to the first direction DR1, the second metal pattern MSP2 may be in contact with the side surface of the third light control pattern CCP-R1, the second portion PP2 of the bank BMP may be in contact with the side surface of the second metal pattern MSP2, and the second light control pattern CCP-G1 may be in contact with the side surface of the second portion PP2.

The light control layer CCL-a may further include a first barrier layer CAP1 disposed on a surface of each of the light control patterns CCP-B, CCP-G1, and CCP-R1, and a second barrier layer CAP2 disposed on another surface of each of the light control patterns CCP-B, CCP-G1, and CCP-R1. The first barrier layer CAP1 may be disposed along the stepped portion between the bank BMP and the light control patterns CCP-B, CCP-G1, and CCP-R1.

Referring to FIG. 6C, the light control layer CCL-b according to an embodiment may include a bank BMP′, and the bank BMP′ may include a first portion PP1′ disposed on a side of the first light control pattern CCP-B, and a second portion PP2′ that does not overlap the first light control pattern CCP-B in a plan view. The first portion PP1′ and the second portion PP2′ may have an integrated shape. The first portion PP1′ and the second portion PP2′ may include a same material and may be formed through a same process. A portion of the bank BMP′ may overlap the third light control pattern CCP-G in a plan view. A portion of the size BMP′ may be disposed on the third light control pattern CCP-G. The bank BMP′ may include a first portion PP1′ disposed on a surface of the third light control pattern CCP-G and a second portion PP2′ that does not overlap the third light control pattern CCP-G in a plan view. The first portion PP1′ may be disposed on (e.g., directly on) the top surfaces of the first light control pattern CCP-B and the third light control pattern CCP-G.

The light control layer CCL-b according to an embodiment may include a metal pattern MSP′, and a portion of the metal pattern MSP′ may overlap the bank BMP′ in a plan view. The metal pattern MSP′ may include a first metal pattern MSP1′ disposed between the first light control pattern CCP-B and the second light control pattern CCP-R and a second metal pattern MSP2′ disposed between the second light control pattern CCP-R and the third light control patterns CCP-G.

A portion of the metal pattern MSP′ may overlap at least a portion of the first light control pattern CCP-B and the second light control pattern CCP-R in a plan view. As illustrated in FIG. 6C, a portion of the metal pattern MSP′ may overlap the first light control pattern CCP-R in a plan view. A portion of the metal pattern MSP′ may be disposed below the second light control pattern CCP-R. A portion of each of the first metal pattern MSP1′ and the second metal pattern MSP2′ may be disposed below the second light control pattern CCP-R.

The first metal pattern MSP1′ may be disposed between the second light control pattern CCP-R and the bank BMP′. The first metal pattern MSP1′ may be disposed adjacent to at least a side surface of the second light control pattern CCP-R and may be disposed between the second portion PP2′ and the second light control pattern CCP-R in the first direction DR1. A portion of the first metal pattern MSP1′ may be disposed on the second portion PP2′. At least a portion of the first metal pattern MSP1′ may be in contact with the second light control pattern CCP-R. A portion of the first metal pattern MSP1′ may be in contact with the side surface of the second light control pattern CCP-R, and a portion of the first metal pattern MSP1′ may be in contact with a portion of the top surface of the second portion PP2′.

The second metal pattern MSP2′ may be disposed between the second light control pattern CCP-R and the bank BMP′. The second metal pattern MSP2′ may be disposed adjacent to at least the side of the second light control pattern CCP-R and may be disposed between the second light control pattern CCP-R and the second portion PP2′ in the first direction DR1. A portion of the second metal pattern MSP2′ may be disposed on the second portion PP2′. At least a portion of the second metal pattern MSP2′ may be in contact with the second light control pattern CCP-R. A portion of the second metal pattern MSP2′ may be in contact with the side surface of the second light control pattern CCP-R, and a portion of the second metal pattern MSP2′ may be in contact with a portion of the top surface of the second portion PP2′.

The metal pattern MSP′ may be provided as a single layer between the first light control pattern CCP-B and the second light control pattern CCP-R. A first metal pattern MSP1′ provided as a single layer may be disposed between the first light control pattern CCP-B and the second light control pattern CCP-R. Based on the first direction DR1, the first metal pattern MSP1′ may be in contact with the side surface of the second light control pattern CCP-R, the second portion PP2′ of the bank BMP′ may be in contact with the side surface of the first metal pattern MSP1′, and the first light control pattern CCP-B may be in contact with the side surface of the second portion PP2′. The metal pattern MSP′ may be provided as a single layer between the second light control pattern CCP-R and the third light control pattern CCP-G. A second metal pattern MSP2′ provided as a single layer may be disposed between the second light control pattern CCP-R and the third light control pattern CCP-G. Based on the first direction DR1, the second metal pattern MSP2′ may be in contact with the side surface of the second light control pattern CCP-R, the second portion PP2′ of the bank BMP′ may be in contact with the side surface of the second metal pattern MSP2′, and the third light control pattern CCP-G may be in contact with the side surface of the second portion PP2′.

The metal pattern MSP′ may include a reflective metal. The metal pattern MSP′ may include a highly reflective metal. The metal pattern MSP′ may include, for example, Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture (e.g., a mixture of Ag and Mg) thereof, which have high reflectivity.

In the light control layer CCL-b according to an embodiment, the bank BMP′ may further include a valley portion BMP-VP. The valley portion BMP-VP may be adjacent to the first light control pattern CCP-B in the first direction DR1 and may be a portion that is recessed in the thickness direction by removing a portion of the bank BMP′. In the first direction DR1, a width of the valley portion BMP-VP may be less than a width of each of the first to third bank openings BOH1, BOH2, and BOH3. The metal pattern MSP′ may further include a third metal pattern MSP3′ disposed inside the valley portion BMP-VP. The bank BMP′ of the light control layer CCL-b according to an embodiment may further include the valley portion BMP-VP to prevent light leakage between adjacent light control patterns. For example, the valley portion BMP-VP may block light between the adjacent first light control pattern CCP-B and third light control pattern CCP-G to prevent the light between the adjacent first light control pattern CCP-B and third light control pattern CCP-G from leaking. In the light control layer CCL-b according to an embodiment, the light leakage between adjacent light control patterns may be prevented by the third metal pattern MSP3′ disposed inside the valley portion BMP-VP.

FIGS. 7A and 7B are enlarged plan views illustrating a portion of partial components of the display panel according to an embodiment of the disclosure. FIG. 7A schematically illustrates planar shapes of bank openings BOH respectively corresponding to the first to third pixel areas PXA-B, PXA-R, and PXA-G included in one pixel unit PXA-U illustrated in FIG. 2. FIG. 7B schematically illustrates a planar arrangement structure of some of the light control patterns respectively corresponding to the first to third pixel areas PXA-B, PXA-R, and PXA-G included in one pixel unit PXA-U illustrated in FIG. 2, the metal pattern MSP, and the additional metal pattern MSP-a.

Referring to FIGS. 2, 4A, 7A, and 7B together, each of the first to third bank openings BOH1, BOH2, and BOH3 may have a rectangular shape having a short side SS1 extending in the first direction DR1 and a long side SS2 extending in the second direction DR2 with respect to the first to third bank openings BOH1, BOH2, BOH3 corresponding to one pixel unit PXA-U. The bank opening BOH may include an additional bank opening BOHa provided adjacent to a short side of at least one of the first to third bank openings BOH1, BOH2, and BOH3. The additional bank opening BOHa may be provided, for example, adjacent to the short side SS1 of the second bank opening BOH2. The additional bank opening BOHa may be parallel to the second bank opening BOH2 in the second direction DR2 and may be spaced a distance from the second bank opening BOH2.

Each of the first light control pattern CCP-B and the third light control pattern CCP-G may be provided to correspond to the first bank opening BOH1 and the third bank opening BOH3, respectively. Each of the first light control pattern CCP-B and the third light control pattern CCP-G may entirely overlap each of the first bank opening BOH1 and the third bank opening BOH3 in a plan view.

The light control layer CCL of the display panel DP according to an embodiment may further include an additional light control pattern CCP-ad provided to correspond to the additional bank opening BOHa. The additional light control pattern CCP-ad, the first light control pattern CCP-B, and the third light control pattern CCP-G may include a same material and may be formed through a same process. The additional light control pattern CCP-ad may be formed by a photoresist process and may include a photosensitive resin. The additional light control pattern CCP-ad may further include a scatterer.

The metal pattern MSP described above may be arranged along an edge of each of the first light control pattern CCP-B and the third light control pattern CCP-G in a plan view. The first metal pattern MSP1 may be disposed between at least the first bank opening BOH1 and the second bank opening BOH2, overlap at least a portion of the first light control pattern CCP-B, and have a square ring shape in a plan view along the edge of the control pattern CCP-B. The second metal pattern MSP2 may be disposed between at least the second bank opening BOH2 and the third bank opening BOH3, overlap at least a portion of the third light control pattern CCP-G, and have a square ring shape in a plan view along the edge of the third control pattern CCP-G.

The light control layer CCL according to an embodiment may further include an additional metal pattern MSP-a. The additional metal pattern MSP-a may be disposed along an edge of the additional light control pattern CCP-ad in a plan view. The additional metal pattern MSP-a may be disposed between at least the second bank opening BOH2 and the additional bank opening BOHa, overlap at least a portion of the additional light control pattern CCP-ad, and have a square ring shape in a plan view along the edge of the additional light control pattern CCP-ad. The additional light control pattern CCP-ad and the additional metal pattern MSP-a may be provided to prevent color from being mixed between pixel units PXA-U that are adjacently disposed in the second direction DR2.

Hereinafter, a method for manufacturing a display panel according to an embodiment of the disclosure will be described.

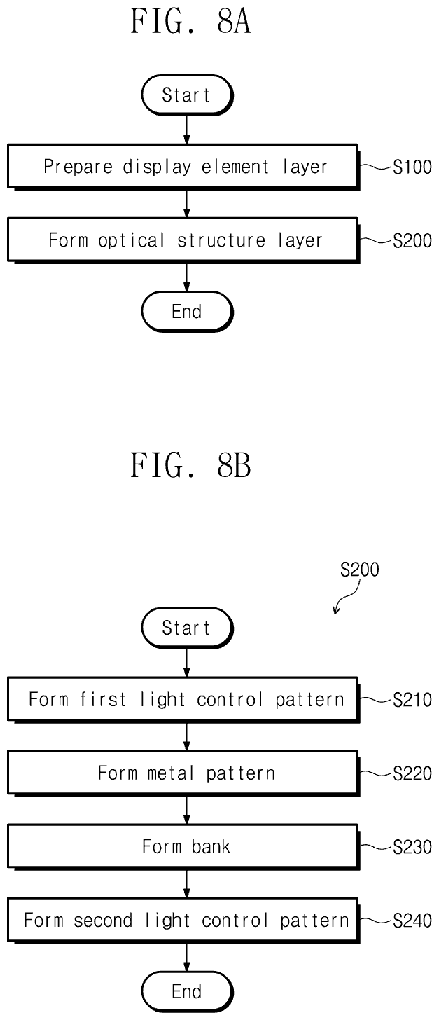

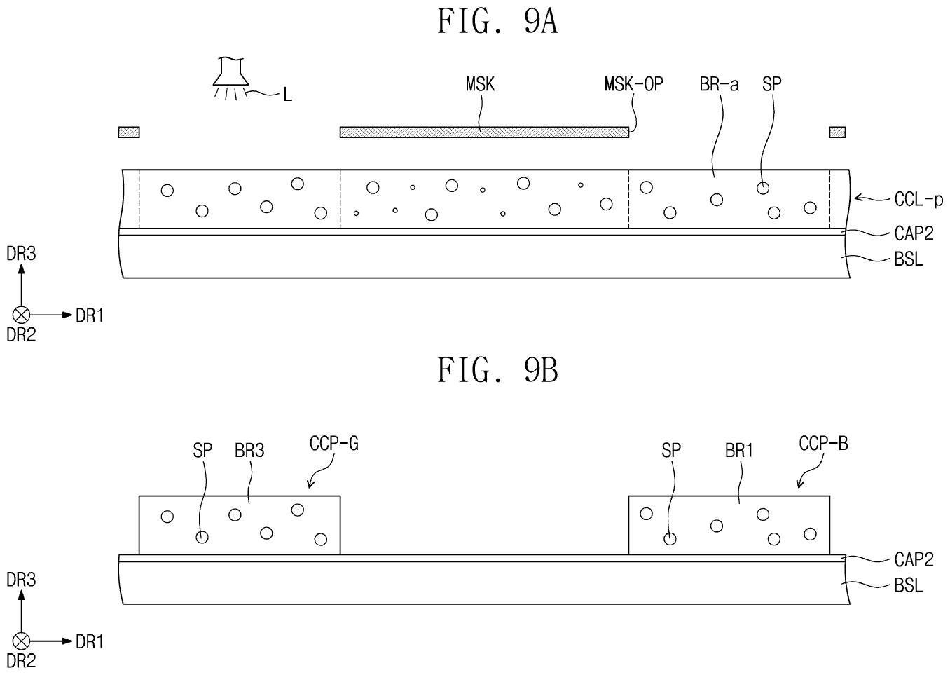

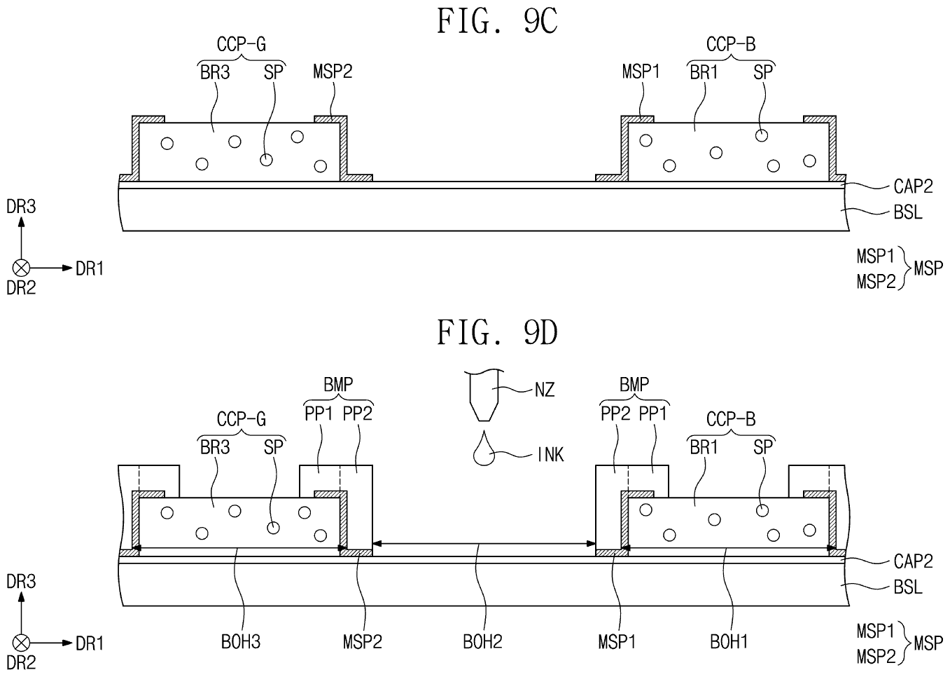

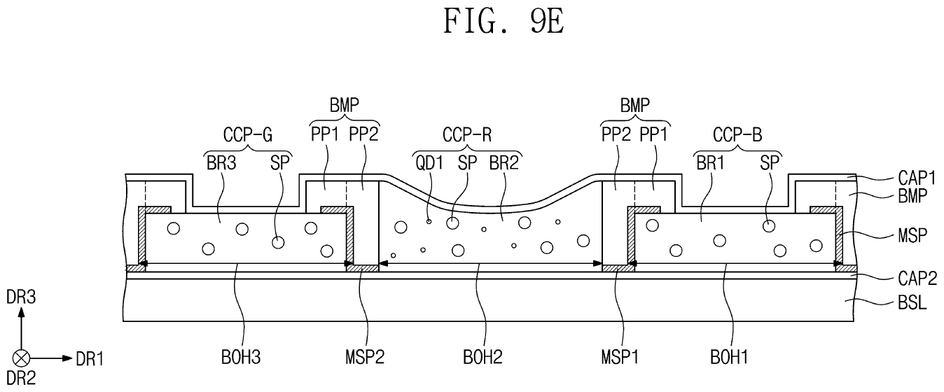

FIG. 8A is a flowchart illustrating a method for manufacturing a display panel according to an embodiment of the disclosure. FIG. 8B is a flowchart illustrating a partial process in the method for manufacturing the display panel according to an embodiment of the disclosure. FIGS. 9A to 9E are schematic cross-sectional views illustrating a partial process in the method for manufacturing the display panel according to an embodiment of the disclosure. FIGS. 9A to 9E schematically illustrate some processes of forming an optical structure layer in a method for manufacturing a display panel according to an embodiment.

Referring to FIG. 8A, the method for manufacturing the display panel according to an embodiment may include a process (S100) of preparing a display element layer including a light emitting element that outputs source light, and a process (S200) of forming an optical structure layer on the light-emitting element. In the method for manufacturing the display panel according to an embodiment, the process of forming the optical structure layer may include a process (S210) of patterning a photosensitive material to form a first optical control pattern, a process (S220) of depositing and patterning a reflective metal layer to form a metal pattern, a process (S230) of forming and patterning an optically transparent preliminary bank to form a bank including a first bank opening, through which the first light control pattern is exposed, and a second bank opening adjacent to the first bank opening in a first direction, and a process (S240) of forming a second light control pattern in the second bank opening through an inkjet process.

Referring to FIGS. 8B, 9A, and 9B, a method for manufacturing the display panel according to an embodiment may include a process (S210) of patterning a first preliminary layer CCL-p including a photosensitive material to form the first light control pattern CCP-B. The first preliminary layer CCL-p may include a base resin BR-a including a photosensitive resin and a scatterer SP. The first preliminary layer CCL-p may be formed by applying a base resin BR-a including a photosensitive resin and a photoresist material including a scatterer SP. The first preliminary layer CCL-p may be provided entirely on the base member BSL and the second barrier layer CAP2, and an uncured portion after an exposure process, in which light L is provided, may be removed to form the first light control pattern CCP-B. In the process of patterning the first preliminary layer CCL-p, a mask MSK may be provided to perform an exposure process on only a portion of the layer. The mask MSK may include a mask opening MSK-OP that overlaps a portion of the first preliminary layer CCL-p in a plan view, and the light L may be irradiated onto a portion of the first preliminary layer CCL-p exposed by the mask opening MSK-OP. The mask MSK may be disposed above the first preliminary layer CCL-p and may be spaced apart from the first preliminary layer CCL-p. The mask opening MSK-OP may be provided to correspond to a portion at which the light control patterns CCP-B and CCP-G will be formed. The first preliminary layer CCL-p may be provided entirely on a base member BSL, and the uncured portion after the exposure process, in which the light L is provided, may be removed to form the first light control pattern CCP-B and the third light control pattern CCP-G. Although FIG. 9B illustrates that the light L is irradiated onto the first preliminary layer CCL-p corresponding to a portion at which the first light control pattern CCP-B and the third light control pattern CCP-G will be formed, i.e., the base resin BR-a includes negative photoresist, the disclosure is not limited thereto. For example, the base resin BR-a of the first preliminary layer CCL-p may include a positive photoresist at a portion, to which the light L is irradiated, except for the portion the first light control pattern CCP-B and the third light control pattern CCP-G will be formed.

Referring to FIGS. 8B, 9B, and 9C, the method for manufacturing the display panel according to an embodiment may include a process (S220) of depositing and patterning a reflective metal layer to form a metal pattern MSP. The metal pattern MSP may include a first metal pattern MSP1 and a second metal pattern MSP2. A portion of the first metal pattern MSP1 may be disposed on the first light control pattern CCP-B. A portion of the first metal pattern MSP1 may be in contact with the side surface of the first light control pattern CCP-B, and a portion of the first metal pattern MSP1 may be in contact with a portion of the top surface of the first light control pattern CCP-B. A portion of the second metal pattern MSP2 may be disposed on the third light control pattern CCP-G. A portion of the second metal pattern MSP2 may be in contact with the side surface of the third light control pattern CCP-G, and a portion of the second metal pattern MSP2 may be in contact with a portion of the top surface of the third light control pattern CCP-G. The metal pattern MSP may be provided as a single layer that covers a portion of the side and top surfaces of each of the first light control pattern CCP-B and the third light control pattern CCP-G.

The metal pattern MSP may include a reflective metal. The metal pattern MSP may be formed by patterning a single metal layer formed by depositing a metal having high reflectivity. The metal pattern MSP' may include, for example, Ag, Mg, Cu, Al, Pt, Pd, Au, Ni, Nd, Ir, Cr, Li, Ca, LiF/Ca, LiF/Al, Mo, Ti, W, In, Zn, Sn, or a compound or mixture (e.g., a mixture of Ag and Mg) thereof, which have high reflectivity.

Referring to FIGS. 8B, 9C, and 9D, the method for manufacturing the display panel according to an embodiment may include a process (S230) of forming and patterning a transparent preliminary bank layer to form a bank BMP including a first bank opening BOH1, through which a portion of the first light control pattern CCP-B is exposed, and a second bank opening BOH2 adjacent the first bank opening BOH1 in the first direction DR1.

The first bank opening BOH1, the second bank opening BOH2, and the third bank opening BOH3 may be formed in the bank BMP. The bank BMP may be formed by patterning each of the first bank opening BOH1, the second bank opening BOH2, and the third bank opening BOH3 after the optically transparent preliminary bank layer is formed. The preliminary bank layer may be formed to cover each of the first light control pattern CCP-B and the third light control pattern CCP-G.

As illustrated in FIG. 9D, a portion of the bank BMP may be formed to overlap the first light control pattern CCP-B in a plan view. A portion of the bank BMP may be formed on the first light control pattern CCP-B. The bank BMP may include a first portion PP1 disposed on a side of the first light control pattern CCP-B, and a second portion PP2 that does not overlap the first light control pattern CCP-B in a plan view. The first portion PP1 and the second portion PP2 may have an integrated shape. The first portion PP1 and the second portion PP2 may include a same material and may be formed through a same process.

A portion of the bank BMP may be formed to overlap the third light control pattern CCP-G in a plan view. A portion of the bank BMP may be formed on the third light control pattern CCP-G. The bank BMP may include a first portion PP1 disposed on a side of the third light control pattern CCP-G, and a second portion PP2 that does not overlap the third light control pattern CCP-G in a plan view.

FIGS. 9B to 9D schematically illustrates an embodiment, in which the metal pattern MSP is formed first, and the bank BMP that covers at least a portion of the metal pattern MSP is formed in the method for manufacturing the display panel according to an embodiment, but the disclosure is not limited thereto. For example, the formation order of the metal pattern MSP and the bank BMP may be changed. For example, unlike that is illustrated in FIGS. 9B to 9D, after the bank BMP is formed first, a metal pattern MSP′ (see FIG. 6C) that covers a portion of the bank BMP may be formed. In case that the bank BMP is formed first, and the metal pattern MSP′ (see FIG. 6C) is formed later, as illustrated in FIG. 6C, the metal pattern MSP′ may be formed to cover a side surface and a portion of a top surface of the second portion PP2 of the bank BMP.

Referring to FIGS. 8B, 9D, and 9E, the method for manufacturing the display panel according to an embodiment may include a process (S240) of forming a second light control pattern CCP-R in the second bank opening BOH2 through an inkjet process.

The second light control pattern CCP-R may be formed by providing ink INK into the second bank opening BOH2 through a nozzle NZ. The ink INK forming the second light control pattern CCP-R may include a first quantum dot QD1. The ink INK may include a first quantum dot QD1 and a scatterer SP and also may include a second base resin BR2 in which the first quantum dot QD1 and the scatterer SP are dispersed. The second base resin BR2 may be an inkjet resin. After the second light control pattern CCP-R is formed, a first barrier layer CAP1 covering a surface of each of the light control patterns CCP-B, CCP-R, and CCP-G may be formed.

According to an embodiment of the disclosure, a portion of the light control pattern included in the light control layer may be formed as a photoresist pattern, a portion of the optically transparent bank may cover the light control pattern formed as the photoresist pattern, and the metal pattern made of a metal may be disposed at a side of the light control pattern. Therefore, the light conversion efficiency of the light control layer may be improved, and the area on which the metal pattern is disposed may be widely secured while increasing in aperture ratio of the bank to improve the display efficiency of the display panel including the light control layer while having the high resolution.

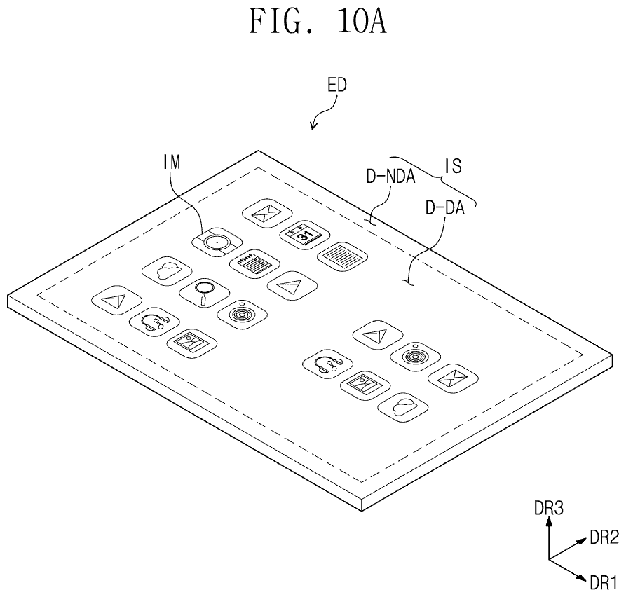

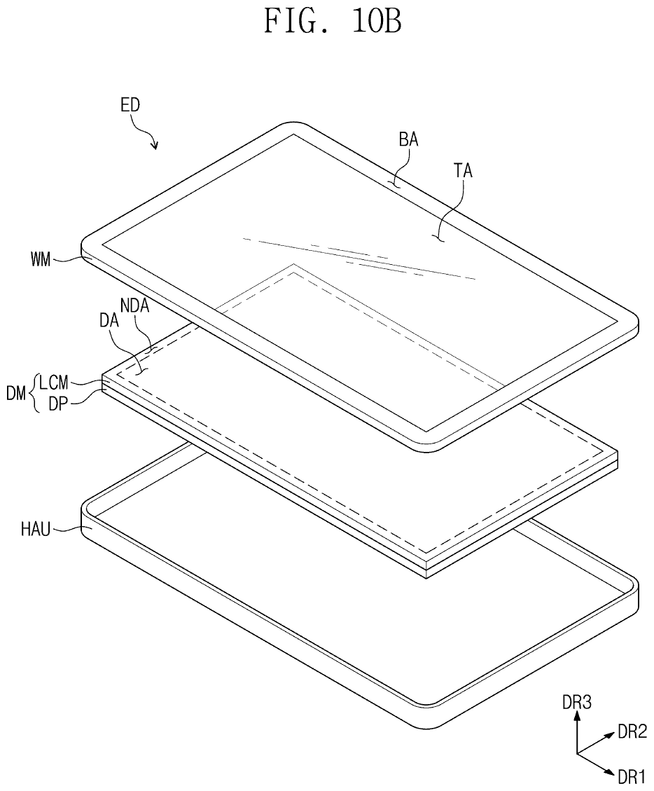

FIG. 10A is a perspective view of an electronic device according to an embodiment of the disclosure. FIG. 10B is an exploded perspective view of the electronic device according to an embodiment of the disclosure.

The electronic device ED may be activated according to an electrical signal and display an image. The electronic device ED may include various embodiments, and for example, the electronic device ED may include large devices such as televisions and external billboards, and small and medium-sized devices such as monitors, mobile phones, tablet computers, navigation systems, and game machines. Meanwhile, the embodiments of the electronic device ED are exemplary and the inventive concept is not limited to any one embodiment as long as they do not depart from the concept of the present invention.

The electronic device ED may display an image IM in a third direction DR3 through a display surface IS parallel to a plane defined by a first direction DR1 and a second direction DR2. The third direction DR3 may be parallel to a normal direction of the display surface IS. The display surface IS on which the image IM is displayed may correspond to the front surface of the electronic device ED. The image IM may include a still image as well as a dynamic image. FIG. 10A illustrates icon images as an example of the image IM.

FIG. 10A exemplarily illustrates the electronic device ED having a flat display surface IS. However, the shape of the display surface IS of the electronic device ED is not limited thereto and may be a curved shape or a three-dimensional shape.

The electronic device ED may be flexible. The term “flexible” refers to a property of being bendable, and a flexible structure may include everything from a completely foldable structure to a structure that can be bent to the level of several nanometers. For example, the flexible electronic device ED may include a curved display device or a foldable display device. However, without being limited thereto, the electronic device ED may be a rigid one.

The display surface IS of the electronic device ED may include a display region D-DA and a peripheral region D-NDA. An image IM may be displayed in the display region D-DA. A user may visually recognize the image IM through the display region D-DA. In an embodiment of the inventive concept illustrated in FIG. 10A, etc., the display region D-DA is illustrated as having a rectangular shape, but this is illustrated as an example, and the display region D-DA may have various shapes.

The peripheral region D-NDA may be a non-display portion that does not display an image IM. The peripheral region D-NDA may correspond to a portion that has a predetermined color and blocks light. The peripheral region D-NDA may be adjacent to the display region D-DA. For example, the peripheral region D-NDA may be disposed outside at least one side of the display region D-DA, and the peripheral region D-NDA may surround the display region D-DA. However, this is illustrated as an example, and the peripheral region D-NDA may be adjacent only to one side of the display region D-DA or may be disposed on a side surface other than the front surface of the electronic device ED, and without being limited thereto, the peripheral region D-NDA may be omitted.

Meanwhile, the electronic device ED according to an embodiment of the inventive concept may sense an external input applied from the outside. The external input may have various forms such as pressure, temperature, and light provided from the outside. The external input may include an input applied at a place close to the electronic device ED (e.g., hovering) as well as an input that contacts the electronic device ED (e.g., a touch by a user's hand or a pen).

Referring to FIG. 10B, the electronic device ED may include a window WM, a display module DM, and a housing HAU, wherein the display module DM may include a display panel DP and a light control member LCM. The window WM and the housing HAU may be coupled to each other to define the appearance of the electronic device ED and may provide an internal space for accommodating the elements of the electronic device ED such as the display module DM.

The window WM may be disposed on the display module DM. The window WM may protect the display module DM from an external impact. The front surface of the window WM may correspond to the aforementioned display surface IS of the electronic device ED. The front surface of the window WM may include a transmission region TA and a bezel region BA.

The transmission region TA of the window WM may be an optically transparent region. The window WM may transmit an image provided by the display module DM through the transmission region TA, and a user may visually recognize the corresponding image. The transmission region TA may correspond to the display region D-DA of the electronic device ED.

The window WM may include an optically transparent insulating material. For example, the window WM may include glass, sapphire, or plastic. The window WM may have a single-layered or multi-layered structure. The window WM may further include functional layers such as an anti-fingerprint layer, a phase control layer, and a hard coating layer which are disposed on an optically transparent substrate.

The bezel region BA of the window WM may be provided as a region on which a material having a predetermined color is deposited, coated, or printed. The bezel region BA of the window WM may prevent a configuration of the display module DM, which is disposed to overlap the bezel region BA, from being visually recognized from the outside. The bezel region BA may correspond to the peripheral region D-NDA of the electronic device ED.

The display module DM may display an image according to an electrical signal. The display module DM may include a display region DA and a non-display region NDA adjacent to the display region DA.

The display region DA may be a portion corresponding to the display region D-DA (see FIG. 10A) of the electronic device ED. The display region DA may be activated according to an electrical signal. The display region DA may be a region configured to display an image provided by the display module DM. The display region DA of the display module DM may correspond to the aforementioned transmission region TA. Meanwhile, in this specification, the expression “a region/portion corresponds to another region/portion” means that “they overlap each other”, but the expression is not limited to having a same area and/or a same shape. An image displayed on the display region DA may be visually recognized from the outside through the transmission region TA.

The non-display region NDA may be adjacent to the display region DA. For example, the non-display region NDA may surround the display region DA. However, without being limited thereto, the non-display region NDA may be defined in various shapes. The non-display region NDA may correspond to the peripheral region D-NDA (see FIG. 10A) of the electronic device ED. The non-display region NDA may be a region in which a driving circuit or driving line configured to drive the display region DA, various signal lines configured to provide electrical signals, and pads are disposed. The non-display region NDA of the display module DM may correspond to the aforementioned bezel region BA. The elements of the display module DM disposed in the non-display region NDA may be prevented from being visually recognized by the bezel region BA.

The display panel DP according to an embodiment of the inventive concept may be a light-emitting display panel and is not particularly limited thereto. For example, the display panel DP may be an organic light-emitting display panel, an inorganic light-emitting display panel, or a quantum dot light-emitting display panel. The light-emitting layer of the organic light-emitting display panel may contain an organic light-emitting material, and the light-emitting layer of the inorganic light-emitting display panel may contain an inorganic light-emitting material. The light-emitting layer of the quantum dot light-emitting display panel may contain quantum dots, quantum rods, and the like. Hereinafter, the display panel DP will be described as an organic light-emitting display panel.

The light control member LCM may be disposed on the display panel DP. After the light control member LCM is provided on the display panel DP, the light control member LCM may be coupled to the display panel DP through a bonding process using a sealing member.

However, without being limited thereto, the light control member LCM may be disposed directly on the display panel DP. In this specification, being formed by a continuous process without a separate adhesive layer or adhesive member may be expressed as “being directly disposed”. For example, the expression “the light control member LCM is disposed directly on the display panel DP” may mean that the configuration of the light control member LCM is formed through a continuous process on a base surface provided by the display panel DP after the display panel DP is formed.

The light control member LCM may include light control patterns capable of converting the optical properties of a source light provided from the display panel DP. The light control member LCM may selectively convert the wavelength or color of the source light or transmit the source light. The light control member LCM may control the color purity or color reproducibility of light emitted from the electronic device ED and prevent reflection of external light incident from the outside of the electronic device ED. For example, in an embodiment of the inventive concept, the light control member LCM may include quantum dots that convert the wavelength of the source light provided from the display panel DP.

The housing HAU may be disposed below and accommodate the display module DM. Since the housing HAU absorbs a shock applied from the outside and prevents foreign substances/moisture from entering into the display module DM, the housing HAU may protect the display module DM. The housing HAU according to an embodiment of the inventive concept may be provided in a form in which a plurality of accommodation members are coupled to each other.

Meanwhile, the display module DM may further include an input detection unit. The input detection unit may obtain the coordinate information of an external input applied from the outside of the electronic device ED. The input detection unit may be disposed between the display panel DP and the light control member LCM. For example, the input detection unit may be disposed directly on the display panel DP through a continuous process, or without being limited thereto, may be separately manufactured and attached to the display panel DP by an adhesive layer.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a display element layer comprising a light emitting element that outputs a source light; and
an optical structure layer disposed on the light emitting element and transmitting the source light or converting the source light into light having a different wavelength, wherein
the optical structure layer comprises a light control layer disposed on the light emitting element,
the light control layer comprises:
a bank comprising a first bank opening and a second bank opening, which are adjacent to each other in a first direction;
a first light control pattern disposed inside the first bank opening;
a second light control pattern disposed inside the second bank opening; and
a metal pattern disposed between the first light control pattern and the second light control pattern,
the bank is optically transparent,
a portion of the bank overlaps the first light control pattern in a plan view, and
a portion of the metal pattern overlaps at least a portion of the first light control pattern and the second light control pattern in a plan view.

2. The display panel of claim 1, wherein the bank comprises a material having transmittance greater than or equal to about 85% in a visible light range.

3. The display panel of claim 1, wherein the metal pattern is disposed between the first light control pattern and the bank and is in contact with at least a portion of a side surface of the first light control pattern.

4. The display panel of claim 1, wherein the metal pattern is disposed between the second light control pattern and the bank and is in contact with at least a portion of a side surface of the second light control pattern.

5. The display panel of claim 1, wherein the metal pattern has a ring shape along an edge of at least one of the first light control pattern and the second light control pattern in a plan view.

6. The display panel of claim 1, wherein
the bank further comprises a third bank opening adjacent to the second bank opening in the first direction, and
the light control layer further comprises a third light control pattern disposed inside the third bank opening.

7. The display panel of claim 6, wherein the metal pattern comprises:
a first metal pattern disposed between the first light control pattern and the second light control pattern in the first direction; and
a second metal pattern disposed between the second light control pattern and the third light control pattern in the first direction.

8. The display panel of claim 6, wherein each of the first light control pattern and the third light control pattern comprises a photosensitive resin.

9. The display panel of claim 6, wherein each of the first light control pattern and the third light control pattern comprises a scatterer and does not comprise an emitter.

10. The display panel of claim 1, wherein the second light control pattern comprises a base resin and a quantum dot that is dispersed in the base resin.

11. The display panel of claim 1, wherein a thickness of the second light control pattern is greater than a thickness of the first light control pattern.

12. The display panel of claim 1, wherein
the bank further comprises:
a first portion disposed on a surface of the first light control pattern; and
a second portion that does not overlap the first light control pattern in a plan view, and
the first portion and the second portion have an integrated shape.

13. The display panel of claim 12, wherein a width of the first portion in the first direction is greater than a width of the second portion in the first direction.

14. The display panel of claim 12, wherein the first portion does not overlap the first light control pattern and overlaps the second light control pattern in the first direction.

15. The display panel of claim 1, wherein
a first bank area defined by the first bank opening emits light having a first wavelength,
a second bank area defined by the second bank opening emits light having a second wavelength, and
the first wavelength is less than the second wavelength.

16. The display panel of claim 1, wherein
the display element layer further comprises an encapsulation layer that covers the light emitting element, and
the light control layer is disposed directly on the encapsulation layer.

17. The display panel of claim 1, wherein
the optical structure layer further comprises a color filter layer comprising a first color filter and a second color filter,
the first color filter overlaps at least the first light control pattern in a plan view, and
the second color filter overlaps at least the second light control pattern in a plan view.

18. The display panel of claim 1, wherein the light control layer further comprises a barrier layer that covers a surface of each of the first light control pattern and the second light control pattern.

19. A display panel comprising:
a display element layer comprising a light emitting element that outputs a source light; and
an optical structure layer disposed on the light emitting element and transmitting the source light or converting the source light into light having a different wavelength, wherein
the optical structure layer comprises a light control layer disposed on the light emitting element,
the light control layer comprises:
a bank comprising a first bank opening, a second bank opening, and a third bank opening, which are arranged in a first direction;
a first light control pattern disposed inside the first bank opening;
a second light control pattern disposed inside the second bank opening;
a third light control pattern disposed inside the third bank opening; and
a metal pattern disposed at least between the first light control pattern and the second light control pattern,
the bank is optically transparent,
each of the first light control pattern and the third light control pattern comprises a photosensitive resin, and
the second light control pattern comprises a base resin and a quantum dot.

20. A method for manufacturing a display panel, the method comprising:
preparing a display element layer comprising a light emitting element that outputs source light; and
forming an optical structure layer on the light emitting element, wherein
the forming of the optical structure layer comprises:
patterning a first preliminary layer comprising a photosensitive material to form a first light control pattern;
depositing and patterning a reflective metal layer to form a metal pattern;
forming and patterning a preliminary bank layer that is optically transparent to form a bank comprising a first bank opening, through which a portion of the first light control pattern is exposed, and a second bank opening adjacent to the first bank opening in a first direction; and
forming a second light control pattern in the second bank opening through an inkjet process,
a portion of the bank overlaps the first light control pattern in a plan view, and
a portion of the metal pattern overlaps at least a portion of the first light control pattern and the second light control pattern in a plan view.

21. An electronic device comprising:
a display panel;
a window disposed on the display panel; and
a housing disposed under the display panel, wherein
the display panel comprises:
a display element layer comprising a light emitting element that outputs a source light; and
an optical structure layer disposed on the light emitting element and transmitting the source light or converting the source light into light having a different wavelength,
the optical structure layer comprises a light control layer disposed on the light emitting element,
the light control layer comprises:
a bank comprising a first bank opening and a second bank opening, which are adjacent to each other in a first direction;
a first light control pattern disposed inside the first bank opening;
a second light control pattern disposed inside the second bank opening; and
a metal pattern disposed between the first light control pattern and the second light control pattern,
the bank is optically transparent,
a portion of the bank overlaps the first light control pattern in a plan view, and
a portion of the metal pattern overlaps at least a portion of the first light control pattern and the second light control pattern in a plan view.
